(19) United States
(12) Patent Application Publication
(10) Pub. No.: US 2026/0006967 A1
(43) Pub. Date: Jan. 1, 2026

(54) DISPLAY DEVICE AND ELECTRONIC DEVICE

(71) Applicant: Samsung Display Co., LTD., Yongin-si (KR)

(72) Inventors: Hoo Keun PARK, Yongin-si (KR); Jong Moo HUH, Yongin-si (KR); Moon Jung AN, Yongin-si (KR); Seok Jin KANG, Yongin-si (KR)

(73) Assignee: Samsung Display Co., LTD., Yongin-si (KR)

(21) Appl. No.: 19/184,491

(22) Filed: Apr. 21, 2025

(30) Foreign Application Priority Data
Jun. 26, 2024 (KR) 10-2024-0083878
Jul. 9, 2024 (KR) 10-2024-0090534

(51) Int. Cl. H10H 29/80; H10H 29/01; H10H 29/39

(52) U.S. Cl. CPC H10H 29/8321; H10H 29/032; H10H 29/39; H10H 29/8325; H10H 29/842

(57) ABSTRACT

A display device includes an anode electrode; a cathode electrode disposed on the anode electrode; a light-emitting element disposed between the anode electrode and the cathode electrode; and an auxiliary electrode surrounding a side surface of the light-emitting element. The light-emitting element includes a bonding electrode connected to the anode electrode; a light-emitting member including a first semiconductor layer connected to the bonding electrode, a second semiconductor layer connected to the cathode electrode and disposed on the first semiconductor layer, and an active layer disposed between the first and second semiconductor layers; and an insulating film covering at least a side surface of the light-emitting member. A portion of the auxiliary electrode that surrounds the side surface of the light-emitting element is disposed above an upper surface of the active layer.

### CROSS-REFERENCE TO RELATED APPLICATION(S)

This application claims priority to and benefits of Korean Patent Application No. 10-2024-0083878, filed on Jun. 26, 2024, and No. 10-2024-0090534, filed on Jul. 9, 2024, under 35 U.S.C. § 119, the entire contents of which are incorporated herein by reference.

### BACKGROUND

### 1. Technical Field

The disclosure relates to a display device and an electronic device.

### 2. Description of Related Art

A display device includes pixels. The pixels may include one or more sub-pixels. Each of the sub-pixels may include at least one light-emitting element that generates light. The pixels may emit light of various colors and luminances, depending on the combination of light emitted from the sub-pixels included in the pixels.

Recently, display devices using inorganic light-emitting elements, such as micro-scale or nano-scale light-emitting diodes (e.g., Micro LEDs), have gained attention.

### SUMMARY

The embodiments may provide a display device capable of improving the light emission efficiency of a light-emitting element.

A display device according to embodiments may include an anode electrode; a cathode electrode disposed on the anode electrode; a light-emitting element disposed between the anode electrode and the cathode electrode; and an auxiliary electrode surrounding a side surface of the light-emitting element. The light-emitting element may include a bonding electrode connected to the anode electrode; a light-emitting member including a first semiconductor layer connected to the bonding electrode, a second semiconductor layer connected to the cathode electrode and disposed on the first semiconductor layer, and an active layer disposed between the first semiconductor layer and the second semiconductor layer; and an insulating film covering at least a side surface of the light-emitting member. A portion of the auxiliary electrode surrounding the side surface of the light-emitting element may be disposed above an upper surface of the active layer.

In an embodiment, the auxiliary electrode may be in contact with the cathode electrode.

In an embodiment, the auxiliary electrode may extend from the side surface of the light-emitting element and cover the entire upper surface of the light-emitting element.

In an embodiment, the auxiliary electrode may be disposed between the cathode electrode and the upper surface of the second semiconductor layer.

In an embodiment, the auxiliary electrode may be in direct contact with the insulating film.

In an embodiment, the display device may further include a first passivation layer disposed on the anode electrode. The light-emitting element may be partially buried in the first passivation layer.

In an embodiment, in cross-section, the height of the upper surface of the first passivation layer may be equal to or higher than the height of the upper surface of the active layer.

In an embodiment, the auxiliary electrode may be disposed on the first passivation layer.

In an embodiment, the auxiliary electrode may be spaced apart from the cathode electrode.

In an embodiment, the display device may further include an auxiliary voltage line connected to the auxiliary electrode.

A display device according to embodiments may include an anode electrode; a cathode electrode disposed on the anode electrode; a light-emitting element disposed between the anode electrode and the cathode electrode; and an auxiliary electrode surrounding a side surface of the light-emitting element. The light-emitting element may include a bonding electrode connected to the anode electrode; a light-emitting member including a first semiconductor layer connected to the bonding electrode, a second semiconductor layer connected to the cathode electrode and disposed on the first semiconductor layer, and an active layer disposed between the first semiconductor layer and the second semiconductor layer; and an insulating film covering at least a side surface of the light-emitting member. A portion of the auxiliary electrode surrounding the side surface of the light-emitting element may be disposed below a lower surface of the active layer.

In an embodiment, the auxiliary electrode may be in direct contact with the insulating film.

In an embodiment, the display device may further include a first passivation layer disposed on the anode electrode; and a second passivation layer disposed on the first passivation layer, wherein the light-emitting element may be partially buried in the first and second passivation layers.

In an embodiment, the height of an upper surface of the second passivation layer may be equal to or lower than the height of the lower surface of the active layer.

In an embodiment, the auxiliary electrode may be disposed on the first passivation layer.

In an embodiment, the display device may further include an auxiliary voltage line connected to the auxiliary electrode.

An electronic device according to embodiments may include a processor that provides image data; and a display device that displays an image based on the image data. The display device may include an anode electrode; a cathode electrode disposed on the anode electrode; and a light-emitting element disposed between the anode electrode and the cathode electrode. The light-emitting element may include a bonding electrode connected to the anode electrode; an auxiliary electrode disposed on the bonding electrode; a light-emitting member including a first semiconductor layer connected to the auxiliary electrode, a second semiconductor layer connected to the cathode electrode and disposed on the first semiconductor layer, and an active layer disposed between the first semiconductor layer and the second semiconductor layer; and an insulating film covering at least a side surface of the light-emitting member. The auxiliary electrode may surround a side surface of the first semiconductor layer below the active layer.

In an embodiment, the auxiliary electrode may be disposed between the auxiliary electrode and the side surface of the first semiconductor layer.

In an embodiment, the auxiliary electrode may be in direct contact with at least a portion of a lower surface of the first semiconductor layer.

In an embodiment, the auxiliary electrode may include a light reflective conductive material.

A display device according to embodiments may include an auxiliary electrode surrounding a side surface of the first semiconductor layer (or the second semiconductor layer). Polarization may be induced in the insulating film by a voltage applied to the auxiliary electrode, which may concentrate the carriers in the first semiconductor layer (or the second semiconductor layer) toward the center, rather than moving to the surface (i.e., the side surface) of the first semiconductor layer (or the second semiconductor layer). This may improve the light emission efficiency of the light-emitting element.

### BRIEF DESCRIPTION OF THE DRAWINGS

The above and other aspects, features, and advantages of embodiments will be more apparent from the following description taken in conjunction with the accompanying drawings, in which:

FIG. 1 is a schematic block diagram illustrating a display device according to an embodiment.

FIG. 2 is a schematic block diagram illustrating a sub-pixel included in the display device of FIG. 1.

FIG. 3 is a schematic plan view illustrating a display panel forming the display device of FIG. 1.

FIG. 4 is a schematic cross-sectional view illustrating an embodiment of the display panel of FIG. 3.

FIG. 5 is a schematic cross-sectional view illustrating another embodiment of the display panel of FIG. 3.

FIG. 6 is a schematic cross-sectional view illustrating a light-emitting element according to an embodiment.

FIG. 7 is a schematic plan view illustrating a first embodiment of a sub-pixel included in the display panel of FIG. 3.

FIG. 8 is a schematic cross-sectional view taken along line X1-X1′ in FIG. 7.

FIG. 9 is an enlarged schematic cross-sectional view of an area of FIG. 8.

FIGS. 10 to 19 are schematic cross-sectional views illustrating a method of manufacturing the sub-pixel of FIG. 8.

FIG. 20 is a schematic plan view illustrating a second embodiment of a sub-pixel included in the display panel of FIG. 3.

FIG. 21 is a schematic cross-sectional view taken along line X2-X2′ in FIG. 20.

FIG. 22 is an enlarged schematic cross-sectional view of an area of FIG. 21.

FIGS. 23 to 30 are schematic cross-sectional views illustrating a method of manufacturing the sub-pixel of FIG. 21.

FIG. 31 is a schematic plan view illustrating a third embodiment of a sub-pixel included in the display panel of FIG. 3.

FIG. 32 is a schematic cross-sectional view taken along line X3-X3′ in FIG. 31.

FIG. 33 is an enlarged schematic cross-sectional view of an area of FIG. 32.

FIGS. 34 to 40 are schematic cross-sectional views illustrating a method of manufacturing the sub-pixel of FIG. 32.

FIG. 41 is a schematic plan view illustrating a fourth embodiment of a sub-pixel included in the display panel of FIG. 3.

FIG. 42 is a schematic cross-sectional view taken along line X4-X4′ in FIG. 41.

FIG. 43 is an enlarged schematic cross-sectional view of an area of FIG. 42.

FIGS. 44 to 52 are schematic cross-sectional views illustrating a method of manufacturing the sub-pixel of FIG. 42.

FIG. 53 is a schematic cross-sectional view illustrating a light-emitting element according to another embodiment.

FIGS. 54 to 61 are schematic cross-sectional views illustrating a method of manufacturing the light-emitting element of FIG. 53.

FIG. 62 is a schematic plan view illustrating a fifth embodiment of a sub-pixel included in the display panel of FIG. 3.

FIG. 63 is a schematic cross-sectional view taken along line X5-X5′ in FIG. 62.

FIG. 64 is an enlarged schematic cross-sectional view of an area of FIG. 63.

FIG. 65 is a schematic block diagram illustrating a display system according to an embodiment.

FIGS. 66 to 69 are schematic perspective views illustrating examples of applications of the display system of FIG. 65.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implemented in another embodiment.

In the drawings, sizes, thicknesses, ratios, and dimensions of the elements may be exaggerated for ease of description and for clarity. Like reference numbers and/or reference characters refer to like elements throughout.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

In the case where an element, such as a layer, a region, a portion, or the like, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

As used herein, the singular forms “a,” “an,” and “the” are intended to include the plural forms as well, unless the context clearly indicates otherwise.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

It will be understood that, although the terms “first,” “second,” etc. may be used herein to describe various elements, these elements should not be limited by these terms. These terms are only used to distinguish one element from another. For example, a first element may be referred to as a second element, and similarly, a second element may be referred to as a first element without departing from the scope of the disclosure.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one element or feature's relationship to another element(s) or feature(s), as illustrated in the drawings. Spatially relative terms are intended to encompass different orientations of an apparatus in use, operation, and/or manufacture in addition to the orientation depicted in the drawings. For example, if the device in the drawings is turned over, elements described as “below” or “beneath” other elements or features would then be oriented “above” the other elements or features. Thus, the term “below” can encompass both an orientation of above and below. Furthermore, the device may be otherwise oriented (e.g., rotated 90 degrees or at other orientations), and, as such, the spatially relative descriptors used herein should interpreted accordingly.

The phrase “in a plan view” means viewing the object from the top, and the phrase “in a schematic cross-sectional view” means viewing a cross-section of which the object is vertically cut from the side. Hence, the expression “in a plan view” used herein may mean that an object is viewed in the third z direction from the top. The phrase “in a schematic cross-sectional view” means viewing a cross-section in the first x direction or the second y direction of which the object is vertically cut from the side. The third z direction also can be referred to as a “thickness direction.”

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device according to embodiments will be described in more detail with reference to the accompanying drawings.

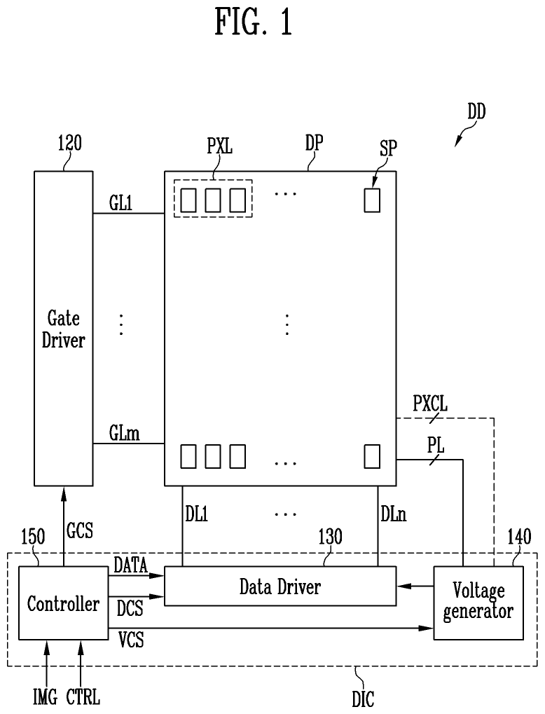

FIG. 1 is a schematic block diagram illustrating a display device according to an embodiment.

Referring to FIG. 1, the display device DD may include a display panel DP, a gate driver 120, a data driver 130, a voltage generator 140, and a controller 150.

The display panel DP may include sub-pixels SPs. The sub-pixels SPs may be connected to the gate driver 120 via a first to m-th gate lines GL1 to GLm. The sub-pixels SPs may be connected to the data driver 130 via a first to n-th data lines DL1 to DLn.

The sub-pixels SPs may generate light of two or more colors. For example, each of the sub-pixels SPs may generate light such as red, green, blue, cyan, magenta, yellow, etc.

Two or more of the sub-pixels SPs may form a pixel PXL. For example, a pixel PXL may include three sub-pixels, as shown in FIG. 1. The pixel PXL may emit light in various colors and luminances, depending on the combination of light emitted from the sub-pixels included in the pixel PXL.

The gate driver 120 may be connected to the sub-pixels SPs arranged in the row direction via the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal, and the like.

The gate driver 120 may be disposed on a side of the display panel DP. However, the embodiments are not limited thereto. For example, the gate driver 120 may be divided into two or more physically and/or logically separated drivers, which may be disposed on a side of the display panel DP and on an opposite side. As such, the gate driver 120 may be disposed around the periphery of the display panel DP in various forms according to embodiments.

The data driver 130 may be connected to the sub-pixels SPs arranged in the column direction via the first to n-th data lines DL1 to DLn. The data driver 130 receives image data DATA and data control signal DCS from the controller 150. The data driver 130 may operate in response to the data control signal DCS. In embodiments, the data control signal DCS may include a source start signal, a source shift clock, a source output enable signal, and the like.

The data driver 130 may receive voltages from the voltage generator 140. The data driver 130 may utilize the received voltages to apply data signals with grayscale voltages corresponding to the image data DATA to the first to n-th data lines DL1 to DLn. In the case where the gate signals are applied to each of the first to m-th gate lines GL1 to GLm, the data signals corresponding to the image data DATA may be applied to the first to n-th data lines DL1 to DLn. Accordingly, the sub-pixels SPs may generate light corresponding to the data signals, and the display panel DP may display the image.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate multiple voltages and provide the generated voltages to components of the display device DD, such as the gate driver 120, the data driver 130, and the controller 150. The voltage generator 140 may generate these voltages by receiving an input voltage from outside the display device DD and regulating the received voltage.

The voltage generator 140 may generate a first power supply voltage and a second power supply voltage. These generated first and second power supply voltages may be provided to the sub-pixels SPs via the power supply lines PLs. In other embodiments, at least one of the first and second power supply voltages may be provided from outside the display device DD.

The voltage generator 140 may provide various voltages and/or signals. For example, the voltage generator 140 may provide one or more initialization voltages applied to the sub-pixels SPs. For example, during a sensing operation to sense electrical characteristics of transistors and/or light emitting elements of the sub-pixels SPs, a reference voltage may be applied to the first to n-th data lines DL1 to DLn, and the voltage generator 140 may generate and transmit the reference voltage to the data driver 130. For example, in a display operation to display an image on the display panel DP, pixel control signals may be commonly applied to the sub-pixels SPs, and the voltage generator 140 may generate the pixel control signals. In embodiments, the voltage generator 140 may provide the pixel control signals to the sub-pixels SPs through the pixel control lines PXCLs. FIG. 1 shows the pixel control lines PXCLs connected between the voltage generator 140 and the display panel DP, but embodiments are not limited thereto. For example, the pixel control lines PXCLs may be connected between the gate driver 120 and the display panel DP. The pixel control signals may be passed from the voltage generator 140 to the pixel control lines PXCLs through the gate driver 120.

The controller 150 may control various operations of the display device DD. The controller 150 may receive input image data IMG and a corresponding control signal CTRL from outside the device. In response to the control signal CTRL, the controller 150 may provide a gate control signal GCS, a data control signal DCS, and a voltage control signal VCS.

The controller 150 may convert the input image data IMG to a format suitable for the display device DD or display panel DP to output image data DATA. In embodiments, the controller 150 may arrange the input image data IMG on a row-by-row basis to output the image data DATA to the sub-pixels SPs.

Two or more components of the data driver 130, voltage generator 140, and controller 150 may be mounted on an integrated circuit. As shown in FIG. 1, the data driver 130, voltage generator 140, and controller 150 may be included in a driver integrated circuit DIC. The data driver 130, voltage generator 140, and controller 150 may be functionally divided components in a driver integrated circuit DIC. In other embodiments, at least one of the data driver 130, voltage generator 140, and controller 150 may be provided as components separated from the driver integrated circuit DIC.

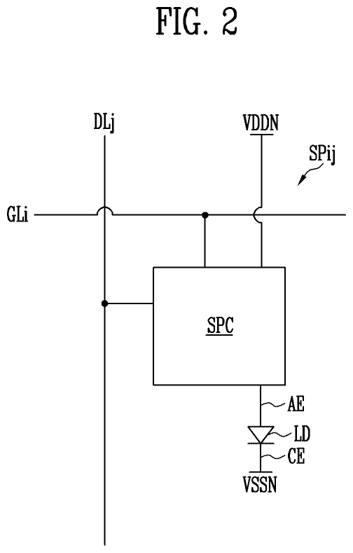

FIG. 2 is a schematic block diagram illustrating a sub-pixel included in the display device in FIG. 1. In FIG. 2, a sub-pixel SPij of the sub-pixels SPs of FIG. 1 arranged in row i (where i is an integer greater than or equal to 1 and less than or equal to m) and column j (where j is an integer greater than or equal to 1 and less than or equal to n) is illustrated.

Referring to FIG. 2, the sub-pixel SPij may include a sub-pixel circuit SPC and a light-emitting element LD.

The light-emitting element LD may be connected between the first power supply voltage node VDDN and the second power supply voltage node VSSN. The first power supply voltage node VDDN may be connected to one of the power supply lines PLs of FIG. 1 to receive a first power supply voltage. The second power supply voltage node VSSN may be connected to another one of the power supply lines PLs of FIG. 1 to receive a second power supply voltage. The first power supply voltage may have a higher level than the second power supply voltage.

The light-emitting element LD may be connected between an anode electrode AE and a cathode electrode CE. The anode electrode AE may be connected to the first power supply voltage node VDDN through the sub-pixel circuit SPC. For example, the anode electrode AE may be connected to the first power supply voltage node VDDN via one or more transistors included in the sub-pixel circuit SPC. The cathode electrode CE may be connected to the second power supply voltage node VSSN. The light-emitting element LD may emit light in response to a current flowing from the anode electrode AE to the cathode electrode CE.

The sub-pixel circuit SPC may be connected to the i-th gate line GLi of the first to m-th gate lines GL1 to GLm in FIG. 1, and to the j-th data line DLj of the first to n-th data lines DL1 to DLn in FIG. 1. In response to the gate signal received via the i-th gate line GLi, the sub-pixel circuit SPC may control the light-emitting element LD to emit light according to the data signal received via the j-th data line DLj. In embodiments, the sub-pixel circuit SPC may be further connected to the pixel control lines PXCLs in FIG. 1. The sub-pixel circuit SPC may control the light-emitting element LD in response to pixel control signals received via the pixel control lines PXCLs.

For these operations, the sub-pixel circuit SPC may include circuit elements, such as transistors and capacitors.

The transistors of the sub-pixel circuit SPC may include P-type transistors and/or N-type transistors. In embodiments, the transistors of the sub-pixel circuit SPC may include metal oxide semiconductor field effect transistors (MOSFETs). In embodiments, the transistors of the sub-pixel circuit SPC may include amorphous silicon semiconductors, monocrystalline silicon semiconductors, polycrystalline silicon semiconductors, oxide semiconductors, and the like.

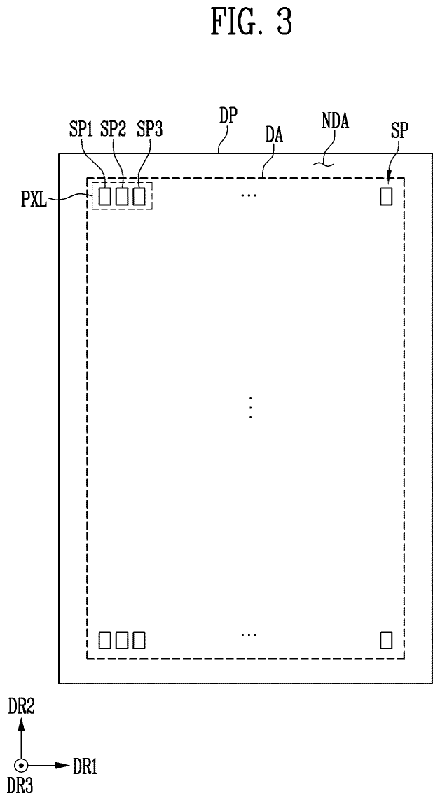

FIG. 3 is a schematic plan view illustrating a display panel forming the display device shown in FIG. 1.

Referring to FIG. 3, the display panel DP may include a display area DA and a non-display area NDA. The display panel DP may display images through the display area DA. The non-display area NDA may be disposed around the periphery of the display area DA.

The display panel DP may include sub-pixels SPs disposed in the display area DA. The sub-pixels SPs may be arranged along a first direction DR1 and a second direction DR2 intersecting the first direction DR1. For example, the sub-pixels SPs may be arranged in a matrix along the first direction DR1 and the second direction DR2. In another example, the sub-pixels SPs may be arranged in a zigzag pattern along the first direction DR1 and the second direction DR2. The arrangement of the sub-pixels SPs may vary according to embodiments. The first direction DR1 may correspond to the row direction and the second direction DR2 may correspond to the column direction.

Two or more of the sub-pixels SPs may form a (or single) pixel PXL. In FIG. 3, a pixel PXL is shown as including three sub-pixels SP1, SP2, and SP3, but embodiments are not limited thereto. For example, the pixel PXL may include two sub-pixels. Hereinafter, for ease of description, it is assumed that the pixel PXL includes first, second, and third sub-pixels SP1, SP2, and SP3.

Each of the first to third sub-pixels SP1, SP2, and SP3 may generate light of one of various colors, such as red, green, blue, cyan, magenta, yellow, and the like. Hereinafter, for clarity and simplicity, it is assumed that the first sub-pixel SP1 generates red-colored light, the second sub-pixel SP2 generates green-colored light, and the third sub-pixel SP3 generates blue-colored light.

Each of the first to third sub-pixels SP1, SP2, and SP3 may include at least one light-emitting element that generates light. In embodiments, the light-emitting elements of the first to third sub-pixels SP1, SP2, and SP3 may generate light of the same color. For example, all the light-emitting elements of the first to third sub-pixels SP1, SP2, and SP3 may generate blue-colored light. In other embodiments, the light-emitting elements of the first to third sub-pixels SP1, SP2, and SP3 may generate light of different colors. For example, the light-emitting elements of the first to third sub-pixels SP1, SP2, and SP3 may generate red-colored, green-colored, and blue-colored light, respectively.

The display panel DP may be a self-luminous display panel, such as a light-emitting diode display panel (LED display panel) that utilizes micro-scale or nano-scale light-emitting diodes as light-emitting elements, or an organic light-emitting display panel (OLED Panel) that utilizes organic light-emitting diodes as light-emitting elements, and the like.

Components for controlling the sub-pixels SPs may be disposed in the non-display area NDA. Wires associated with the sub-pixels SPs, such as the first to m-th gate lines GL1 to GLm, first to n-th data lines DL1 to DLn, power supply lines PLs, and pixel control lines PXCLs shown in FIG. 1, may also be disposed in the non-display area NDA.

At least one of the gate driver 120, the data driver 130, the voltage generator 140, and the controller 150 in FIG. 1 may be disposed in the non-display area NDA of the display panel DP. In embodiments, the gate driver 120 may be disposed in the non-display area NDA. The data driver 130, the voltage generator 140, and the controller 150 may be implemented as the driver integrated circuit DIC in FIG. 1 separate from the display panel DP, and the driver integrated circuit DIC may be connected to wires disposed in the non-display area NDA. In other embodiments, the gate driver 120 may also be implemented as part of an integrated circuit, separate from the display panel DP along with the data driver 130, voltage generator 140, and controller 150.

In embodiments, the display area DA may have various shapes. The display area DA may have a closed-loop shape that includes straight and/or curved sides. For example, the display area DA may be shaped as a polygon, circle, semicircle, ellipse, or the like.

In embodiments, the display area DP may have a flat display surface. In other embodiments, the display area DP may have a surface that is at least partially rounded. In embodiments, the display panel DP may be bendable, foldable, or rollable. The display panel DP and/or the substrate of the display panel DP may include materials having flexible properties.

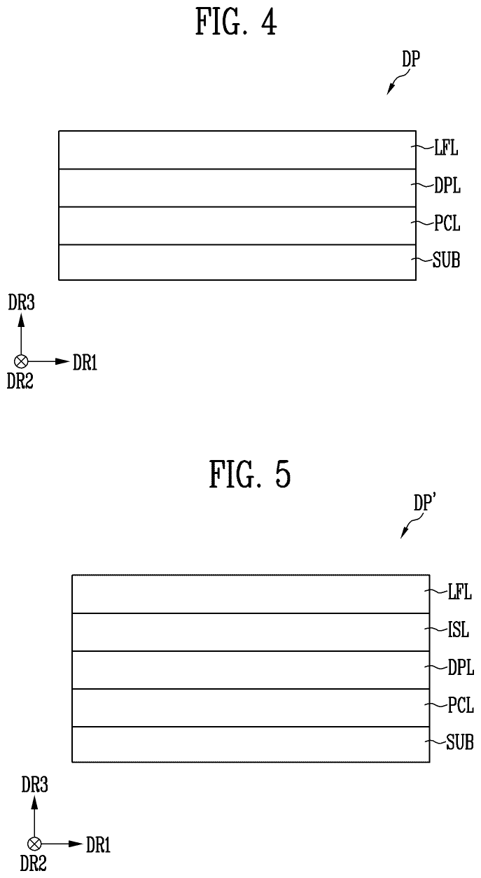

FIG. 4 is a schematic cross-sectional view illustrating an embodiment of the display panel from FIG. 3.

Referring to FIG. 4, the display panel DP may include a substrate SUB, with a pixel circuit layer PCL, a display element layer DPL, and a light functional layer LFL stacked sequentially on the substrate SUB in a third direction DR3 intersecting the first and second directions DR1 and DR2.

The substrate SUB may be made of an insulating material, such as glass or resin. For example, the substrate SUB may include a glass substrate. In another example, the substrate SUB may include a polyimide (PI) substrate. In another example, the substrate SUB may include a silicon wafer substrate formed using a semiconductor process.

In embodiments, the substrate SUB may be made of a material that is flexible enough to be bent or folded, and may have a single-layer structure or a multi-layer structure. For example, flexible materials may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

A pixel circuit layer PCL may be disposed on the substrate SUB. The pixel circuit layer PCL may include insulating layers and semiconductor patterns and conductive patterns disposed between the insulating layers. The conductive patterns of the pixel circuit layer PCL may function as circuit elements, wires, and the like.

The circuit elements in the pixel circuit layer PCL may form a sub-pixel circuit SPC for each of the sub-pixels SPs in FIG. 3. For example, the circuit elements in the pixel circuit layer PCL may be provided by the transistors and one or more capacitors of the sub-pixel circuit SPC.

The wires in the pixel circuit layer PCL may include wires connected to the sub-pixels SPs. These wires in the pixel circuit layer PCL may include various signal lines and/or voltage lines required to drive the display element layer DPL.

A display element layer DPL may be disposed on the pixel circuit layer PCL. The display element layer DPL may include light-emitting elements of the sub-pixels SPs.

A light functional layer LFL may be disposed on the display element layer DPL. The light functional layer LFL may include light conversion patterns having color conversion particles and/or scattering particles. For example, the color conversion particles may include quantum dots. The quantum dots may change the wavelength (or color) of the light emitted from the display element layer DPL. The light functional layer LFL may further include the light scattering patterns having scattering particles. In embodiments, the light conversion patterns and light scattering patterns may be omitted.

The light functional layer LFL may further include a color filter layer including color filters. These color filters may selectively transmit light of desired wavelengths (or colors). In embodiments, the color filter layer may be omitted.

A window may be provided on the light functional layer LFL to protect the exposed surface (or upper surface) of the display panel DP. The window may protect the display panel DP from external impact. The window may be coupled to the light functional layer LFL via an optically transparent bonding (or adhesive) member. The window may have a multilayer structure selected from a glass substrate, a plastic film, and a plastic substrate. The multilayer structure may be formed by a continuous process or by an adhesive process utilizing an adhesive layer. All or part of the window may be flexible.

FIG. 5 is a schematic cross-sectional view illustrating another embodiment of the display panel of FIG. 3.

Referring to FIG. 5, the display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be configured substantially the same as (or similar to) the substrate SUB, the pixel circuit layer PCL, the display element layer DPL, and the light functional layer LFL described with reference to FIG. 4. Accordingly, description of overlapping content is omitted.

The input sensing layer ISL may detect user input on the upper surface (or display surface) of the display panel DP′. The input sensing layer ISL may sense an external object, such as a user's hand, pen, or the like. For example, the input sensing layer ISL may include touch electrodes.

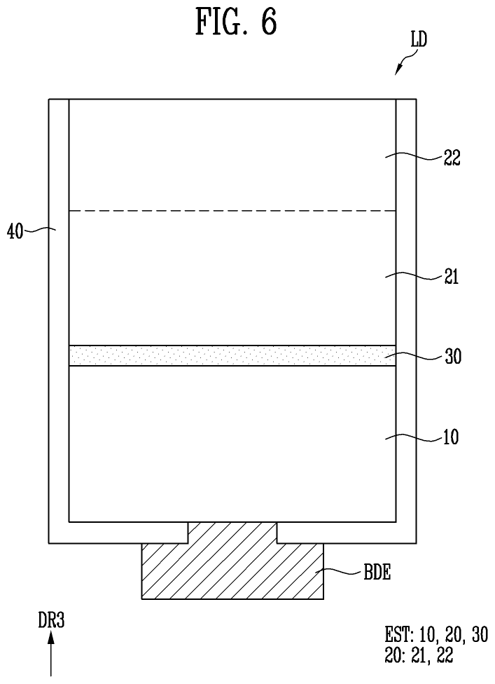

FIG. 6 is a schematic cross-sectional view illustrating a light-emitting element according to an embodiment.

Referring to FIG. 6, the light-emitting element LD may include a bonding electrode BDE, a light-emitting member EST, and an insulating film 40. The light-emitting member EST may include a first semiconductor layer 10, a second semiconductor layer 20, and an active layer 30. The light-emitting element LD may be implemented as a vertical light-emitting member in which the bonding electrode BDE, the first semiconductor layer 10, the active layer 30, and the second semiconductor layer 20 are stacked sequentially along the third direction DR3.

The first semiconductor layer 10 may provide holes. The first semiconductor layer 10 may have a first polarity. For example, the first semiconductor layer 10 may comprise at least one p-type semiconductor layer. For example, the first semiconductor layer 10 may include at least one semiconductor material selected from gallium nitride (GaN), aluminum gallium nitride (AlGaN), indium gallium nitride (InGaN), aluminum nitride (AlN), and indium nitride (InN), and may be a p-type semiconductor layer doped with a first conductive dopant (or p-type dopant) such as magnesium (Mg), zinc (Zn), calcium (Ca), strontium (Sr), barium (Ba), and the like. However, the materials forming the first semiconductor layer 10 are not limited thereto, and various other materials may be used. In an embodiment, the first semiconductor layer 10 may include gallium nitride (GaN) semiconductor material doped with a first conductive dopant (or p-type dopant).

The second semiconductor layer 20 may be disposed on the first semiconductor layer 10 and may provide electrons. The second semiconductor layer 20 may have a second polarity that is different from the first polarity. For example, the second semiconductor layer 20 may comprise at least one n-type semiconductor layer. For example, the second semiconductor layer 20 may include at least one semiconductor material selected from gallium nitride (GaN), aluminum gallium nitride (AlGaN), indium gallium nitride (InGaN), aluminum nitride (AlN), and indium nitride (InN), and may be an n-type semiconductor layer doped with a second conductive dopant (or n-type dopant) such as silicon (Si), germanium (Ge), tin (Sn), or the like. However, the materials forming the second semiconductor layer 20 are not limited thereto, and various other materials may be used. In an embodiment, the second semiconductor layer 20 may include gallium nitride (GaN) semiconductor material doped with a second conductive dopant (or n-type dopant).

In an embodiment, the second semiconductor layer 20 may include a first doped part 21 and a second doped part 22 that are sequentially stacked along the third direction DR3. The first doped part 21 may be a region doped with a relatively high concentration of dopant, and the second doped part 22 may be a region doped with a relatively low concentration of dopant, or may be a region that is substantially undoped. For example, the first average doping concentration of the dopant in the first doped part 21 may be greater than the second average doping concentration of the dopant in the second doped part 22.

The active layer 30 may be disposed (or interposed) between the first semiconductor layer 10 and the second semiconductor layer 20, and may provide a region where electrons and holes recombine. As electrons and holes recombine in the active layer 30, they may transition to lower energy levels, generating light with corresponding wavelengths. The active layer 30 may be formed as a single quantum well structure or as a multiple quantum well structure. In the case where the active layer 30 is formed in a multiple quantum well structure, units including a barrier layer, a strain reinforcing layer (or strain relief layer), and a well layer may be repeatedly stacked to form the active layer 30. However, the active layer 30 is not limited to the structure described above.

The bonding electrode BDE may be disposed below the first semiconductor layer 10. The bonding electrode BDE may be connected to the first semiconductor layer 10. For example, the bonding electrode BDE may contact a portion of lower surface of the first semiconductor layer 10. In an embodiment, the bonding electrode BDE may comprise a eutectic metal.

In an embodiment, a reflective electrode may be further disposed between the bonding electrode BDE and the first semiconductor layer 10. The reflective electrode may improve light emission efficiency of the light emitted from the light-emitting element LD. The reflective electrode may include a conductive material having a selected reflectivity. The conductive material may include an opaque metal. The opaque metal may include, for example, metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, the material of the reflective electrode is not limited thereto.

The insulating film 40 may cover at least a side surface of the light-emitting member EST. For example, the insulating film 40 may cover a side surface of the light-emitting member EST and a portion of the lower surface of the light-emitting member EST. The insulating film 40 may prevent electrical shorts that may occur when the active layer 30 comes into contact with other conductive materials other than the first and second semiconductor layers 10 and 20. In an embodiment, the insulating film 40 may expose the upper surface of the light-emitting member EST.

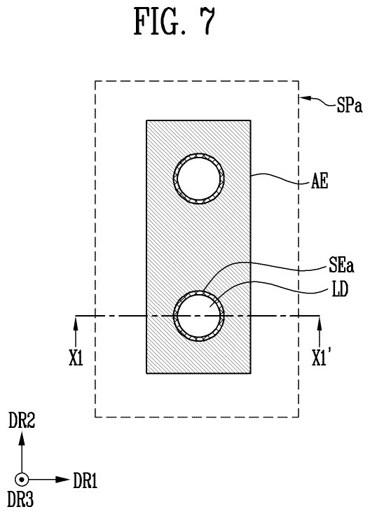

Hereinafter, with reference to FIGS. 7 to 52, sub-pixels SPa, SPb, SPc, and SPd, which include the light-emitting element LD described with reference to FIG. 6, will be described.

FIG. 7 is a schematic plan view illustrating a first embodiment of a sub-pixel included in the display panel of FIG. 3.

Referring to FIG. 7, the sub-pixel SPa may be one of the first to third sub-pixels SP1, SP2, and SP3 of FIG. 3.

The sub-pixel SPa may include an anode electrode AE, a light-emitting element LD, and an auxiliary electrode SEa.

The anode electrode AE may be connected to the sub-pixel circuit (SPC, see FIG. 2) of the sub-pixel SPa.

The light-emitting element LD may be the same as the light-emitting element LD described with reference to FIG. 6. The light-emitting element LD may be connected to the anode electrode AE. The light-emitting element LD may be disposed on the anode electrode AE. In an embodiment, multiple light-emitting elements LDs may be included. For example, as shown in FIG. 7, two light-emitting elements LDs may be provided on the anode electrode AE. In the case where the sub-pixel SPa includes multiple light-emitting elements, the anode electrode AE may extend in a specific direction, such as the second direction DR2, and the light-emitting elements connected to it may be arranged in the same direction.

The auxiliary electrode SEa may surround the side surface of the light-emitting element LD. The auxiliary electrode SEa may improve the luminous efficiency of the light-emitting element LD.

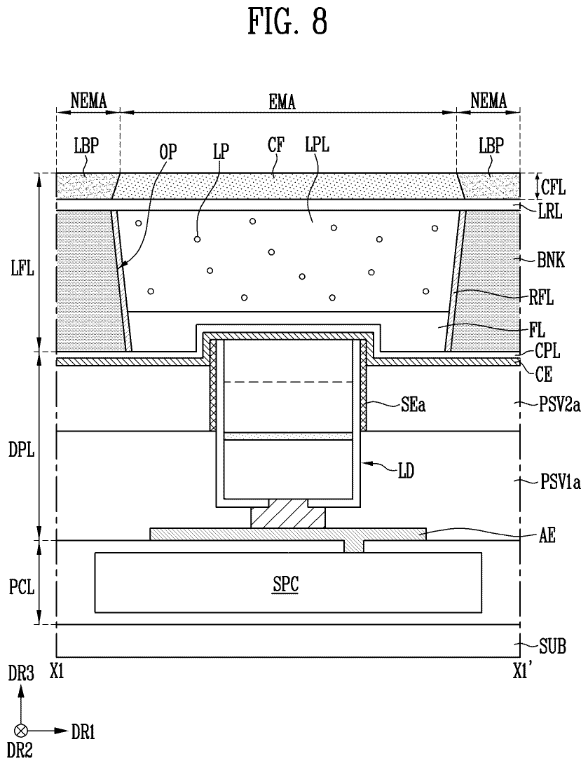

FIG. 8 is a schematic cross-sectional view taken along line X1-X1′ in FIG. 7.

Referring to FIGS. 7 and 8, a pixel circuit layer PCL, a display element layer DPL, and a light functional layer LFL may be sequentially disposed on the substrate SUB.

The pixel circuit layer PCL may include insulating layers, semiconductor patterns, and conductive patterns stacked on the substrate SUB. The semiconductor patterns and conductive patterns may be located between the insulating layers. The semiconductor patterns and conductive patterns in the pixel circuit layer PCL may function as transistors and capacitors in the sub-pixel circuit SPC. The conductive patterns of the pixel circuit layer PCL may further function as wires, for example, the first to m-th gate lines GL1 to GLm, the first to n-th data lines DL1 to DLn, the power supply lines PLs, and the pixel control lines PXCLs in FIG. 1.

A display element layer DPL may be disposed on the pixel circuit layer PCL. The display element layer DPL may include an anode electrode AE, a light-emitting element LD, first and second passivation layers PSV1a and PSV2a, an auxiliary electrode SEa, a cathode electrode CE, and a capping layer CPL.

The anode electrodes AE may be connected to the transistors forming the sub-pixel circuit SPC through contact holes that penetrate the insulating layers of the pixel circuit layer PCL.

The light-emitting element LD may be disposed on the anode electrode AE. The bonding electrode BDE of the light-emitting element LD may be bonded to the anode electrode AE. Through the bonding electrode BDE, the anode electrode AE and the first semiconductor layer 10 may be electrically connected.

The first passivation layer PSV1a may be disposed on the anode electrode AE and the pixel circuit layer PCL. The light-emitting element LD may be partially buried in the first passivation layer PSV1a. The first passivation layer PSV1a may secure the light-emitting element LD bonded to the anode electrode AE, thereby preventing movement.

The first passivation layer PSV1a may include an inorganic insulating layer including an inorganic material and/or an organic insulating layer including an organic material. The inorganic insulating layer may include at least one of, for example, a metal oxide such as silicon oxide, silicon nitride, silicon oxynitride, and aluminum oxide. The organic insulating layer may include at least one of, for example, an acrylic resin, an epoxy resin, a phenol resin, a polyamide resin, a polyimide resin, an unsaturated polyester resin, a poly-phenylene ether resin, a poly-phenylene sulfide resin, and a benzocyclobutene resin.

The upper surface of the first passivation layer PSV1a may be substantially flat. In an embodiment, the height of the upper surface of the first passivation layer PSV1a may be equal to or higher than the height of the upper surface of the active layer 30.

The auxiliary electrode SEa may surround the side surface of the light-emitting element LD. For example, the auxiliary electrode SEa may surround the side surface of the first and second doped parts 21 and 22, forming the second semiconductor layer 20. An insulating film 40 may be disposed (or interposed) between the auxiliary electrode SEa and the light-emitting member EST, and the auxiliary electrode SEa may contact (or directly contact) the insulating film 40. The auxiliary electrode SEa may be disposed above the upper surface of the active layer 30. In an embodiment, the auxiliary electrode SEa may be disposed on the first passivation layer PSV1a.

In an embodiment, the auxiliary electrode SEa may reflect incident light, thereby improving light emission efficiency. For example, the auxiliary electrode SEa may include a light-reflective conductive material. For example, the auxiliary electrode SEa may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

The second passivation layer PSV2a may be disposed on the first passivation layer PSV1a. The second passivation layer PSV2a and the first passivation layer PSV1a may include substantially the same (or similar) material.

The upper surface of the second passivation layer PSV2a may be substantially flat. In an embodiment, the height of the upper surface of the second passivation layer PSV2a may be lower than the height of the upper surface of the light-emitting element LD. The light-emitting element LD may partially protrude above the second passivation layer PSV2a. The auxiliary electrode SEa surrounding the side surface of the light-emitting element LD may also partially protrude above the second passivation layer PSV2a.

In an embodiment, the height of the upper surface of the second passivation layer PSV2a may be higher than the height of the upper surface of the first doped part 21. This may reduce the step difference between the upper surface of the second passivation layer PSV2a and the upper surface of the light-emitting element LD. The cathode electrode CE may be less likely to be disconnected due to the step difference.

The cathode electrode CE may be disposed on the second passivation layer PSV2a, the light-emitting element LD, and the auxiliary electrode SEa, such that it covers the second passivation layer PSV2a, the light-emitting element LD, and the auxiliary electrode SEa. The cathode electrode CE may be electrically connected to the second power supply voltage node VSSN in FIG. 2. Accordingly, a second power supply voltage applied to the second power supply voltage node VSSN may be delivered to the cathode electrode CE.

The cathode electrode CE may be substantially transparent or translucent to meet a selected light transmittance. For example, the cathode electrode CE may include at least one transparent conductive materials, such as indium tin oxide (ITO), indium zinc oxide (IZO), zinc oxide (ZnO), indium gallium zinc oxide (IGZO), indium tin zinc oxide (ITZO), and the like. However, the material of the cathode electrode CE is not limited thereto.

The cathode electrode CE may be connected to the second semiconductor layer 20. For example, the cathode electrode CE may directly contact the upper surface of the second semiconductor layer 20. Through this connection, a second power supply voltage applied to the second power supply voltage node VSSN may be transferred to the second semiconductor layer 20.

In an embodiment, the cathode electrode CE may contact the auxiliary electrode SEa. Accordingly, the auxiliary electrode SEa may receive the second power supply voltage applied to the second power supply voltage node VSSN.

The capping layer CPL may be disposed on the cathode electrode CE. The capping layer CPL may cover the cathode electrode CE. The capping layer CPL may protect components beneath the capping layer CPL, such as the cathode electrode CE, the light-emitting element LD, and the like, from external moisture and humidity. The capping layer CPL may include at least one of silicon nitride, silicon oxide, silicon oxynitride, and a metal oxide such as an aluminum oxide. However, the material of the capping layer CPL is not limited thereto.

A light functional layer LFL may be disposed on the display element layer DPL. The light functional layer LFL may include a bank BNK, a reflective layer RFL, a filling layer FL, a light functional particle layer LPL, a low refractive index layer LRL, and a color filter layer CFL.

The bank BNK may have an opening OP. The bank BNK may include a light-blocking material to prevent light mixing between neighboring sub-pixels. For example, the bank BNK may include an organic insulating material such as an acryl resin, an epoxy resin, a phenol resin, a polyamide resin, a polyimide resin, or the like.

The reflective layer RFL may be disposed on the side surface of the bank BNK adjacent to the opening OP. The reflective layer RFL may reflect incident light, thereby improving light emission efficiency. The reflective layer RFL may include a material suitable for reflecting light. For example, the reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

A filling layer FL may be disposed on the capping layer CPL within the opening OP. The filling layer FL may protect components disposed below it and provide a flat upper surface. The filling layer FL and either the first passivation layer PSV1a or the second passivation layer PSV2a may include the same material, but embodiments are not limited thereto.

The light functional particle layer LPL may be disposed on the filling layer FL within the opening OP. The light functional particle layer LPL may include light functional particles LPs.

In an embodiment, the sub-pixel SPa may be a first sub-pixel SP1 (red sub-pixel). In the case where the light-emitting element LD emits blue-colored light, the light functional particles LPs may include color conversion particles (for example, quantum dots) that convert the blue-colored light to red-colored light. In the case where the light-emitting element LD emits red-colored light, the light functional particles LPs may include scattering particles.

In an embodiment, the sub-pixel SPa may be a second sub-pixel SP2 (green sub-pixel). In the case where the light-emitting element LD emits blue-colored light, the light functional particles LPs may include color conversion particles that convert the blue-colored light to green-colored light. In the case where the light-emitting element LD emits green-colored light, the light functional particles LPs may include scattering particles.

In an embodiment, the sub-pixel SPa may be a third sub-pixel SP3 (blue sub-pixel). In the case where the light-emitting element LD emits blue-colored light, the light functional particles LPs may include scattering particles.

In embodiments, the light functional particle layer LPL may be omitted.

The low refractive index layer LRL may be placed on the bank BNK, the reflective layer RFL, and the light functional particle layer LPL. The low refractive index layer LRL may have a lower refractive index than the light functional particle layer LPL. The low refractive index layer LRL may refract or totally reflect light depending on the angle of incidence of the light. The low refractive index layer LRL may also return light that has passed through the light functional particle layer LPL back to the light functional particle layer LPL. Accordingly, the light conversion efficiency and light scattering efficiency of the light functional particles LPs in the light functional particle layer LPL may be improved. In an embodiment, the low refractive index layer LRL may be omitted in the case where the light functional particles LPs are composed solely of scattering particles.

The color filter layer CFL may be disposed on the low refractive index layer LRL. The color filter layer CFL may include a color filter CF and light-blocking patterns LBPs.

A color filter CF may overlap a light functional particle layer LPL. The color filter CF may selectively transmit light in a desired wavelength range. If the sub-pixel SPa is a red sub-pixel, the color filter CF may be a red color filter. If the sub-pixel SPa is a green sub-pixel, the color filter CF may be a green color filter. If the sub-pixel SPa is a blue sub-pixel, the color filter CF may be a blue color filter.

The light-blocking patterns LBPs may overlap the banks BNKs. The light-emitting area (or, emission area) EMA and non-light-emitting area NEMA of the sub-pixel SPa may be defined by the light-blocking patterns LBPs. Areas that overlap the light-blocking patterns LBPs may be non-light-emitting areas NEMAs, and areas that do not overlap the light-blocking patterns LBPs may be light-emitting areas EMAs.

The light-blocking patterns LBPs may include at least one type of light-blocking material. For example, each of the light-blocking patterns LBPs may be formed as a multilayer in which at least two color filters, such as a red color filter, a green color filter, and a blue color filter, overlap.

In the sub-pixel SPa according to the first embodiment, the auxiliary electrode SEa may surround the side surface of the light-emitting element LD and may be connected to the cathode electrode CE. A voltage applied to the auxiliary electrode SEa (i.e., the second power supply voltage) may cause polarization in the insulating film 40 in contact with the auxiliary electrode SEa. Accordingly, the carriers in the second semiconductor layer 20 may concentrate toward the center rather than moving to the surface (i.e., the side surface) of the second semiconductor layer 20. This may improve the light emission efficiency of the light-emitting element LD.

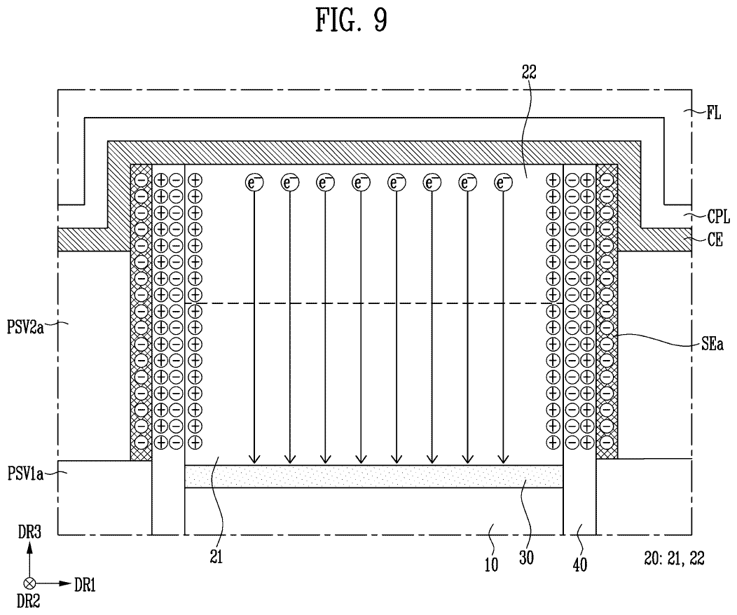

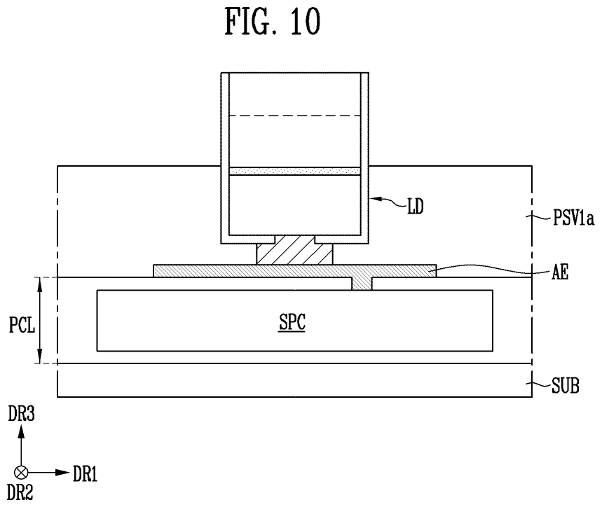

FIG. 9 is an enlarged schematic cross-sectional view of an area of FIG. 8.

Referring to FIGS. 8 and 9, the voltage applied to the auxiliary electrode SEa (i.e., the second power supply voltage) may cause the auxiliary electrode SEa to have a negative polarity. This negative polarity may induce polarization in the insulating film 40. More specifically, a first portion of the insulating film 40 in contact with the auxiliary electrode SEa may have a positive polarity, opposite to the polarity of the auxiliary electrode SEa. A second portion of the insulating film 40, surrounded by the first portion, may have a negative polarity opposite to the polarity of the first portion.

The second portion of the insulating film 40 may be in contact with the second semiconductor layer 20. Extra electrons may be present in the second semiconductor layer 20, which is an n-type semiconductor layer doped with an n-type dopant. Since the second portion of the insulating film 40 has a negative polarity, a repulsive force may exist between the second portion of the insulating film 40 and the extra electrons. Accordingly, the extra electrons may be distributed more in the center rather than on the surface (i.e., side surface) of the second semiconductor layer 20. For example, the extra electrons may be substantially absent or relatively few on the surface (i.e., side surface) of the second semiconductor layer 20. As shown in FIG. 9, the surface (i.e., side surface) of the second semiconductor layer 20 in contact with the second portion of the insulating film 40 may have a positive polarity due to the deficiency of electrons.

As the extra electrons are distributed more in the center rather than on the surface (i.e., side surface) of the second semiconductor layer 20, the electron path in the second semiconductor layer 20 may also be formed in the center of the second semiconductor layer 20. Accordingly, the electrons in the second semiconductor layer 20 may be concentrated toward the center instead of moving to the surface (i.e., side surface) of the second semiconductor layer 20. For example, the electrons in the second semiconductor layer 20 may be more effectively provided to the active layer 30, improving the light emission efficiency of the light-emitting element LD.

FIGS. 10 to 19 are schematic cross-sectional views illustrating a method of manufacturing the sub-pixel of FIG. 8.

Referring to FIG. 10, after bonding the light-emitting element LD to the anode electrode AE, the first passivation layer PSV1a may be formed. In this step, the light-emitting element LD may be partially buried in the first passivation layer PSV1a. The height of the upper surface of the first passivation layer PSV1a may be equal to or higher than the height of the upper surface of the active layer 30.

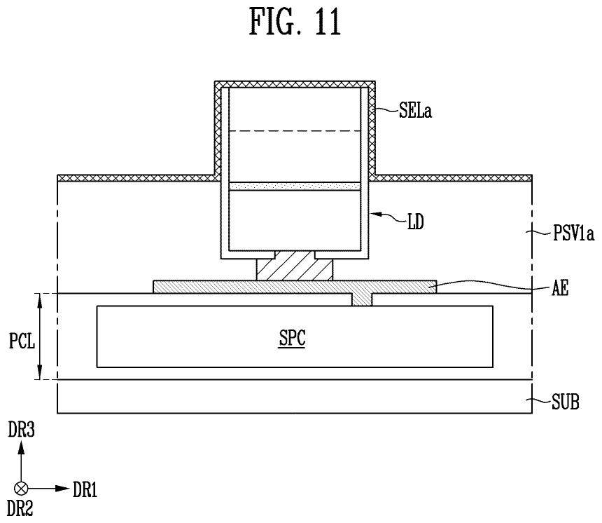

Referring to FIG. 11, an auxiliary electrode layer SELa covering the first passivation layer PSV1a and the light-emitting element LD may be formed. The auxiliary electrode layer SELa may cover the first passivation layer PSV1a and the light-emitting element LD as a whole (or entirely). The auxiliary electrode layer SELa may also cover the portion of the light-emitting element LD protruding above the first passivation layer PSV1a.

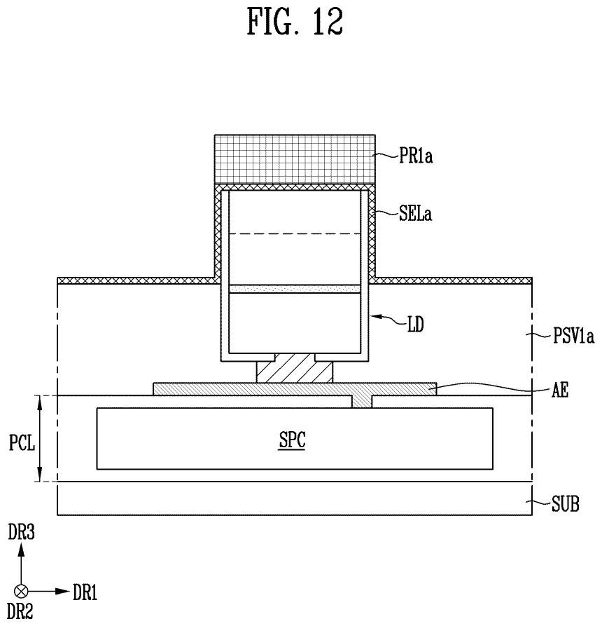

Referring to FIG. 12, a first mask layer PR1a may be formed on the auxiliary electrode layer SELa to overlap the upper surface of the light-emitting element LD. The first mask layer PR1a may include, for example, a photoresist material.

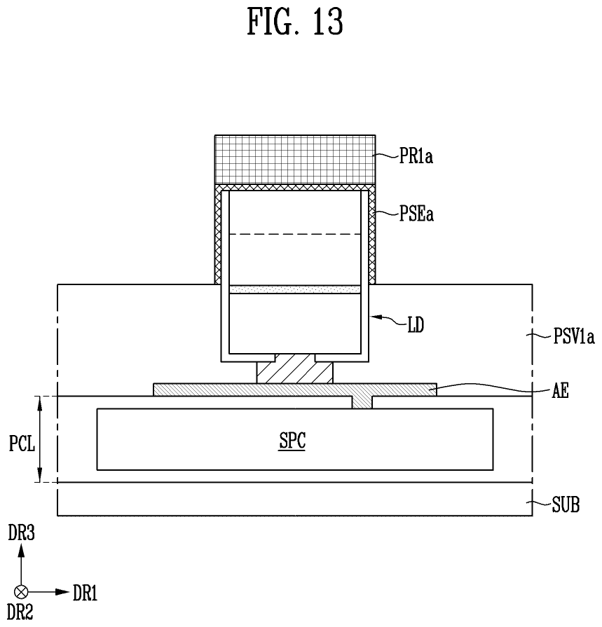

Referring to FIG. 13, a preliminary auxiliary electrode PSEa may be formed by etching the auxiliary electrode layer SELa using the first mask layer PR1a as a mask. In this step, a portion of the auxiliary electrode layer SELa covering the upper surface of the first passivation layer PSV1a may be removed by etching. The preliminary auxiliary electrode PSEa may fully cover the portion of the light-emitting element LD protruding above the first passivation layer PSV1a.

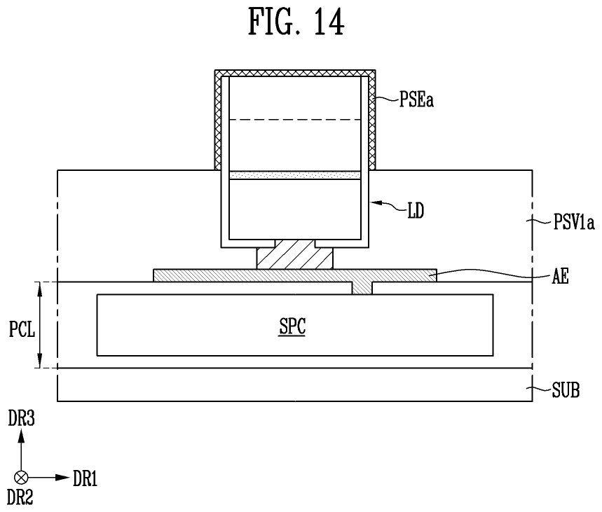

Referring to FIG. 14, the first mask layer PR1a may be removed.

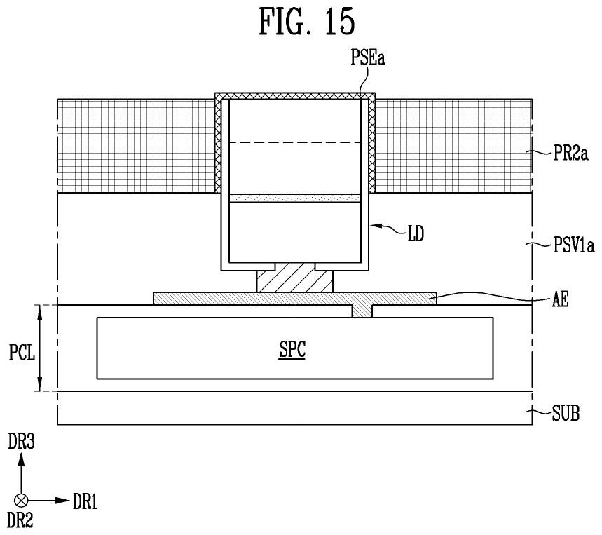

Referring to FIG. 15, a second mask layer PR2a may be formed on the first passivation layer PSV1a to expose a preliminary auxiliary electrode PSEa that overlaps the upper surface of the light-emitting element LD. The second mask layer PR2a may include, for example, a photoresist material.

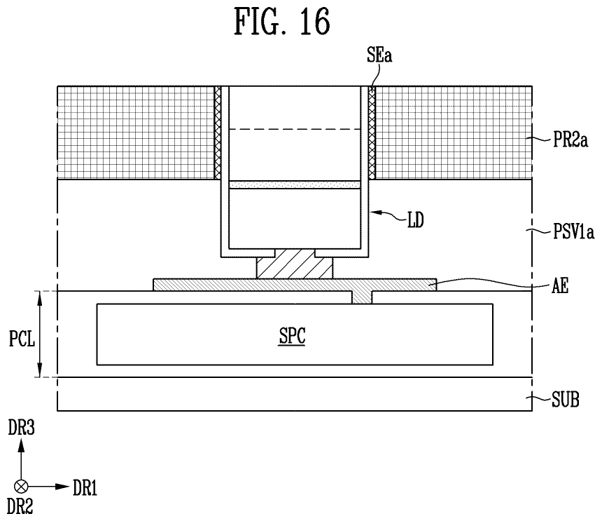

Referring to FIG. 16, an auxiliary electrode SEa may be formed by etching the preliminary auxiliary electrode PSEa using the second mask layer PR2a as a mask. In this step, a portion of the preliminary auxiliary electrode PSEa covering the upper surface of the light-emitting element LD may be removed by etching. The auxiliary electrode SEa may expose the upper surface of the light-emitting element LD and may surround the side surface of the light-emitting element LD protruding above the first passivation layer PSV1a.

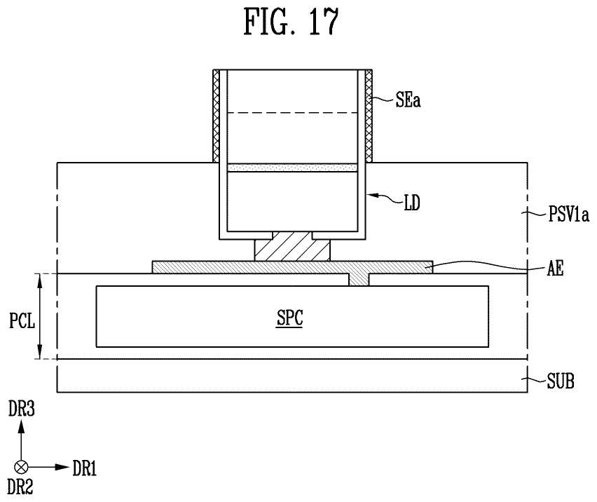

Referring to FIG. 17, the second mask layer PR2a may be removed.

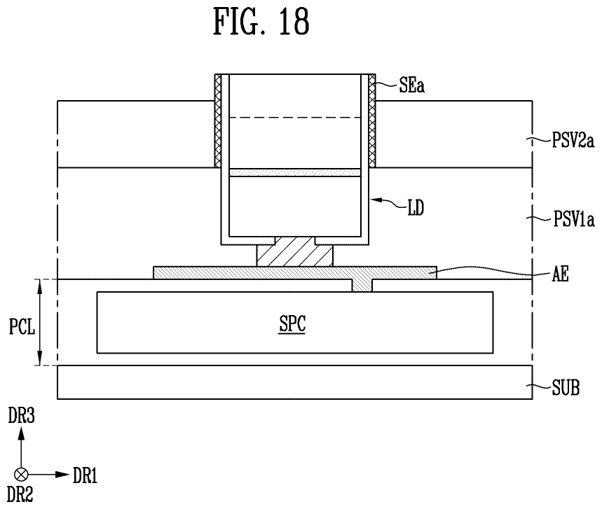

Referring to FIG. 18, a second passivation layer PSV2a may be formed on the first passivation layer PSV1a. The height of the upper surface of the second passivation layer PSV2a may be lower than the height of the upper surface of the light-emitting element LD. The height of the upper surface of the second passivation layer PSV2a may be higher than the height of the upper surface of the first doped part 21.

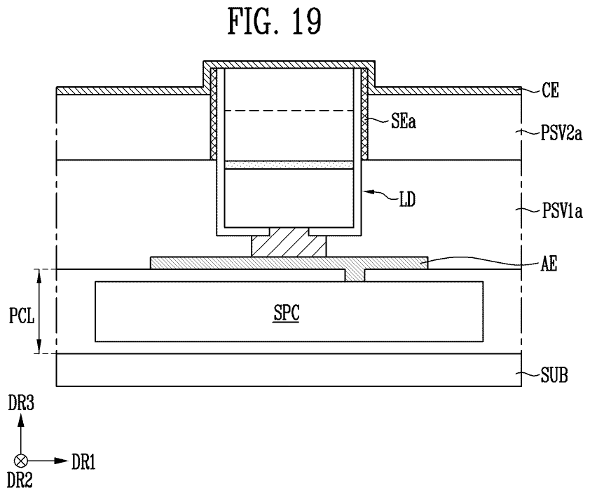

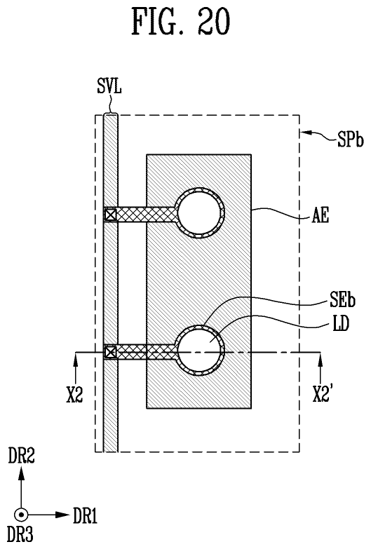

Referring to FIG. 19, a cathode electrode CE may be formed on the second passivation layer PSV2a, the light-emitting element LD, and the auxiliary electrode SEa, covering the second passivation layer PSV2a, the light-emitting element LD, and the auxiliary electrode SEa. The cathode electrode CE may cover a step difference between the upper surface of the second passivation layer PSV2a and the upper surface of the light-emitting element LD. The cathode electrode CE may be prevented from being disconnected due to the relatively small step difference.

The capping layer CPL and the light functional layer LFL described with reference to FIG. 8 may then be formed.

FIG. 20 is a schematic plan view illustrating a second embodiment of a sub-pixel included in the display panel of FIG. 3.

In describing FIG. 20, only the differences from the embodiment described with reference to FIG. 7 will be described, and the omitted parts are replaced with the above descriptions.

Referring to FIG. 20, the sub-pixel SPb may be any one of the first to third sub-pixels SP1, SP2, and SP3 of FIG. 3.

The sub-pixel SPb may include an anode electrode AE, a light-emitting element LD, an auxiliary electrode SEb, and an auxiliary voltage line SVL.

The auxiliary electrode SEb may surround the side surface of the light-emitting element LD. The auxiliary electrode SEb may extend from the light-emitting element LD toward the auxiliary voltage line SVL, and may partially overlap the auxiliary voltage line SVL. The auxiliary electrode SEb may be connected to the auxiliary voltage line SVL through a contact hole and may receive an auxiliary voltage through the auxiliary voltage line SVL.

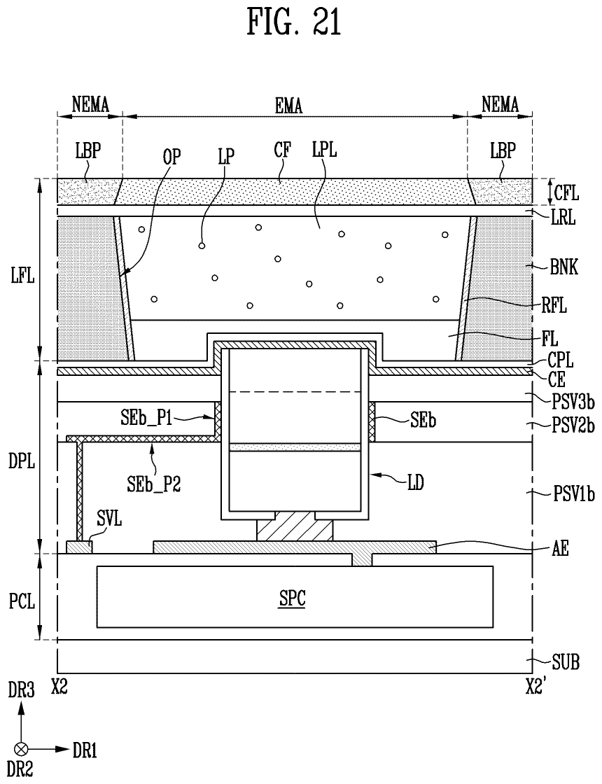

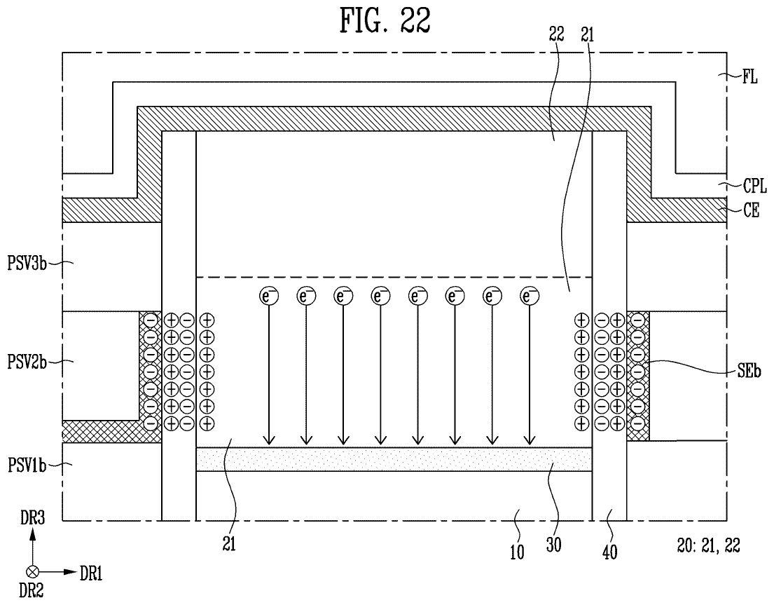

FIG. 21 is a schematic cross-sectional view taken along line X2-X2′ in FIG. 20.

In describing FIG. 21, only the differences from the embodiment described with reference to FIG. 8 will be described, and the omitted parts are replaced with the above descriptions.

Referring to FIGS. 20 and 21, the display element layer DPL may include an anode electrode AE, an auxiliary voltage line SVL, a light-emitting element LD, first to third passivation layers PSV1b, PSV2b, and PSV3b, an auxiliary electrode SEb, a cathode electrode CE, and a capping layer CPL.

The auxiliary voltage line SVL may be spaced apart from the anode electrode AE. In an embodiment, the auxiliary voltage line SVL and the anode electrode AE may be disposed in the same layer. However, the embodiments are not limited thereto. For example, the auxiliary voltage line SVL may be disposed on any one of the insulating layers forming the pixel circuit layer PCL.

The first passivation layer PSV1b may be disposed on the anode electrode AE, the auxiliary voltage line SVL, and the pixel circuit layer PCL. The light-emitting element LD may be partially buried in the first passivation layer PSV1b. The first passivation layer PSV1b may secure the light-emitting element LD bonded to the anode electrode AE, preventing it from moving. The first passivation layer PSV1b may include substantially the same material as the first passivation layer PSV1a described with reference to FIG. 8.

The upper surface of the first passivation layer PSV1b may be substantially flat. In an embodiment, the height of the upper surface of the first passivation layer PSV1b may be equal to or higher than the height of the upper surface of the active layer 30.

The auxiliary electrode SEb may include a first portion SEb_P1 and a second portion SEb_P2.

The first portion SEb_P1 may surround the side surface of the light-emitting element LD. For example, the first portion SEb_P1 may surround the side surface of the first doped part 21 forming the second semiconductor layer 20 of the light-emitting element LD. An insulating film 40 may be disposed between the first portion SEb_P1 and the light-emitting member EST, and the first portion SEb_P1 may be in contact (or direct contact) with the insulating film 40. The first portion SEb_P1 may be disposed above the upper surface of the active layer 30. In an embodiment, the first portion SEb_P1 may be disposed on the first passivation layer PSV1b.

The second portion SEb_P2 may extend from the first portion SEb_P1. For example, the second portion SEb_P2 may extend from the first portion SEb_P1 in a direction opposite to the first direction DR1. The second portion SEb_P2 may not be in contact (or direct contact) with the insulating film 40. The second portion SEb_P2 may partially overlap the auxiliary voltage line SVL. The second portion SEb_P2 may be connected to the auxiliary voltage line SVL via contact holes. In an embodiment, the second portion SEb_P2 may extend along the upper surface of the first passivation layer PSV1b from the first portion SEb_P1.

In an embodiment, the auxiliary electrode SEb may reflect incident light, thereby improving light emission efficiency. For example, the auxiliary electrode SEb may include a light-reflective conductive material. For example, the auxiliary electrode SEb may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

The second passivation layer PSV2b may be disposed on the first passivation layer PSV1b. The second passivation layer PSV2b and the first passivation layer PSV1b may include substantially the same (or similar) material.

The upper surface of the second passivation layer PSV2b may be substantially flat. In an embodiment, the height of the upper surface of the second passivation layer PSV2b may be equal to or lower than the height of the upper surface of the first doped part 21.

In an embodiment, the thickness of the second passivation layer PSV2b in the third direction DR3 may be the same as the thickness of the first portion SEb_P1 in the third direction DR3.

The third passivation layer PSV3b may be disposed on the second passivation layer PSV2b. The third passivation layer PSV3b and the first passivation layer PSV1b may include substantially the same (or similar) material.

The upper surface of the third passivation layer PSV3b may be substantially flat. In an embodiment, the height of the upper surface of the third passivation layer PSV3b may be lower than the height of the upper surface of the light-emitting element LD. The light-emitting element LD may partially protrude above the third passivation layer PSV3b.

In an embodiment, the height of the upper surface of the third passivation layer PSV3b may be higher than the height of the upper surface of the first doped part 21. Accordingly, the step difference between the upper surface of the third passivation layer PSV3b and the upper surface of the light-emitting element LD may be relatively reduced. The cathode electrode CE may be prevented from being disconnected by due to the step difference.

The cathode electrode CE may be disposed on the third passivation layer PSV3b and the light-emitting element LD, covering the third passivation layer PSV3b and the light-emitting element LD. In an embodiment, the cathode electrode CE may be spaced apart from the auxiliary electrode SEb.

In the sub-pixel SPb according to the second embodiment, an auxiliary electrode SEb may surround the side surface of the light-emitting element LD and may be connected to the auxiliary voltage line SVL. The auxiliary voltage line SVL may transmit an auxiliary voltage to the auxiliary electrode SEb. The auxiliary voltage applied to the auxiliary electrode SEb may cause polarization in the insulating film 40 in contact with the auxiliary electrode SEb. Accordingly, the carriers in the second semiconductor layer 20 may concentrate toward the center rather than moving to the surface (i.e., side surface) of the second semiconductor layer 20, improving the light emission efficiency of the light-emitting element LD.

In an embodiment, the auxiliary voltage transmitted through the auxiliary voltage line SVL may be applied at various levels to concentrate the carriers in the second semiconductor layer 20 toward the center by generating polarization in the insulating film 40 in contact with the auxiliary electrode SEb. For example, the auxiliary voltage may have the same (or similar) level as the voltage applied to the cathode electrode CE.

FIG. 22 is an enlarged schematic cross-sectional view of one area of FIG. 21.

Referring to FIGS. 21 and 22, the auxiliary voltage applied to the auxiliary electrode SEb may cause the auxiliary electrode SEb to have a negative polarity. The negative polarity may induce polarization in the insulating film 40. More specifically, a first portion of the insulating film 40 in contact with the auxiliary electrode SEb may have a positive polarity, opposite to the polarity of the auxiliary electrode SEb. A second portion of the insulating film 40, surrounded by the first portion, may have a negative polarity opposite to the polarity of the first portion.

The second portion of the insulating film 40 may be in contact with the second semiconductor layer 20 (or the first doped part 21). Extra electrons may be present in the second semiconductor layer 20, which is an n-type semiconductor layer doped with an n-type dopant. Since the second portion of the insulating film 40 has a negative polarity, a repulsive force may exist between the second portion of the insulating film 40 and the extra electrons. Accordingly, the extra electrons may be distributed more in the center than on the surface (i.e., side surface) of the second semiconductor layer 20. The extra electrons may be substantially absent from the surface (i.e., side surface) of the second semiconductor layer 20 (or the first doped part 21), or may be relatively few in number. As shown in FIG. 22, the surface (i.e., side surface) of the second semiconductor layer 20 (or the first doped part 21) in contact with the second portion of the insulating film 40 may have a positive polarity due to the deficiency of electrons.

As the extra electrons are distributed more in the center rather than on the surface (i.e., side surface) of the second semiconductor layer 20 (or the first doped part 21), the paths of electron movement in the second semiconductor layer 20 (or the first doped part 21) may also be formed in the center of the second semiconductor layer 20 (or the first doped part 21). Accordingly, the electrons in the second semiconductor layer 20 (or the first doped part 21) may be concentrated toward the center instead of moving to the surface (i.e., side surface) of the second semiconductor layer 20 (or the first doped part 21). The electrons in the second semiconductor layer 20 (or the first doped part 21) may be more effectively provided to the active layer 30, thereby improving the light emission efficiency of the light-emitting element LD.

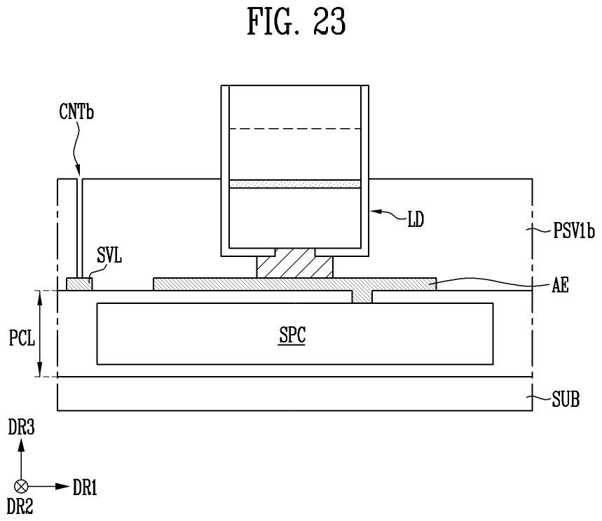

FIGS. 23 to 30 are schematic cross-sectional views illustrating a method of manufacturing the sub-pixel of FIG. 21.

Referring to FIG. 23, after bonding the light-emitting element LD to the anode electrode AE, the first passivation layer PSV1b may be formed. A contact hole CNTb may be formed through the first passivation layer PSV1b to expose the auxiliary voltage line SVL. In this step, the light-emitting element LD may be partially buried in the first passivation layer PSV1b. The height of the upper surface of the first passivation layer PSV1b may be equal to or higher than the height of the upper surface of the active layer 30.

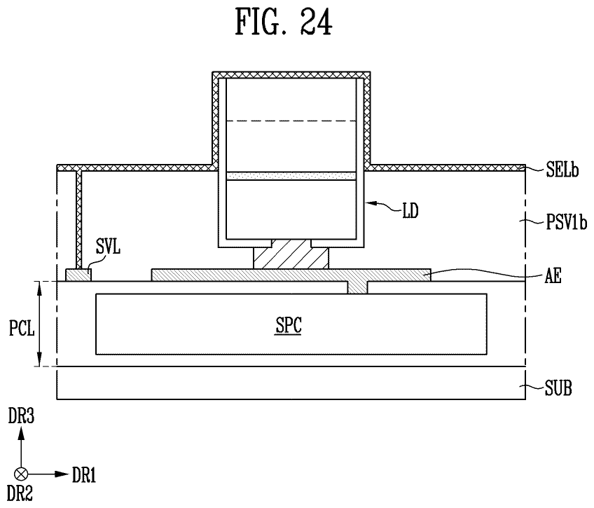

Referring to FIG. 24, an auxiliary electrode layer SELb covering the first passivation layer PSV1b and the light-emitting element LD may be formed. The auxiliary electrode layer SELb may cover both the first passivation layer PSV1b and the light-emitting element LD as a whole (or entirely). The auxiliary electrode layer SELb may be connected to the auxiliary voltage line SVL via the contact hole CNTb. The auxiliary electrode layer SELb may also cover the portion of the light-emitting element LD protruding above the first passivation layer PSV1b.

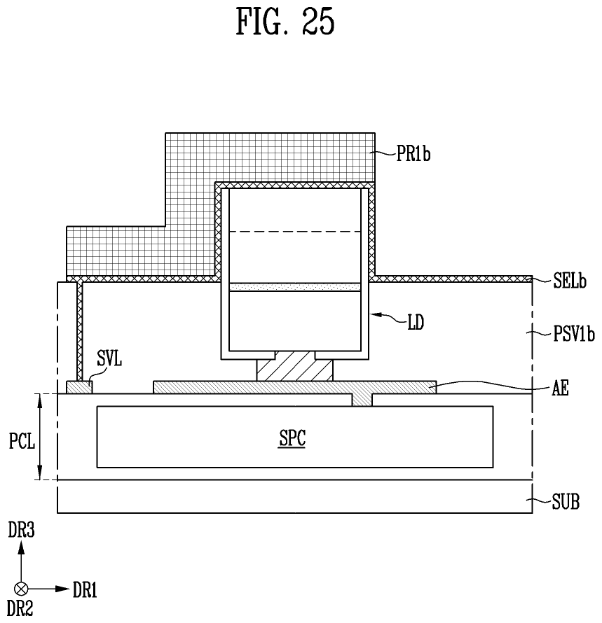

Referring to FIG. 25, a first mask layer PR1b may be formed, extending from the upper surface of the light-emitting element LD to the contact hole CNTb. The first mask layer PR1b may include, for example, a photoresist material.

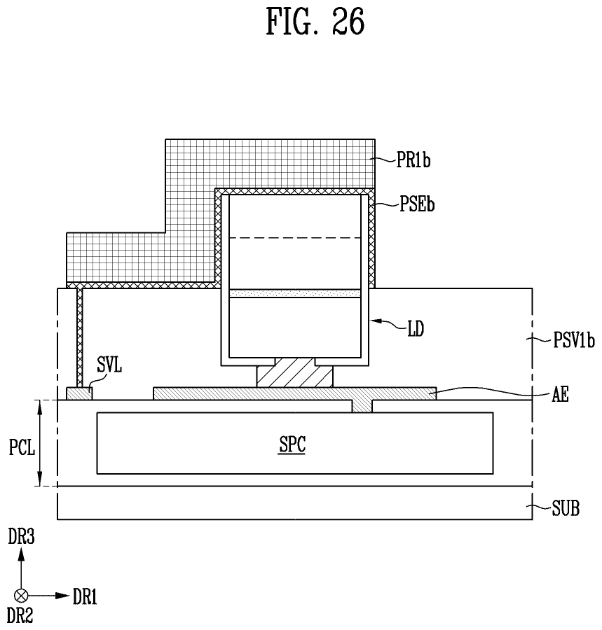

Referring to FIG. 26, a preliminary auxiliary electrode PSEb may be formed by etching the auxiliary electrode layer SELb using the first mask layer PR1b as a mask. In this step, a portion of the auxiliary electrode layer SELb that does not overlap the first mask layer PR1b may be removed by etching. The preliminary auxiliary electrode PSEb may entirely cover the portion of the light-emitting element LD protruding above the first passivation layer PSV1b and may be connected to the auxiliary voltage line SVL via the contact holes CNTb. The preliminary auxiliary electrode PSEb may have substantially the same in-plane shape as the auxiliary electrode SEb described with reference to FIG. 20, except that it covers the upper surface of the light-emitting element LD.

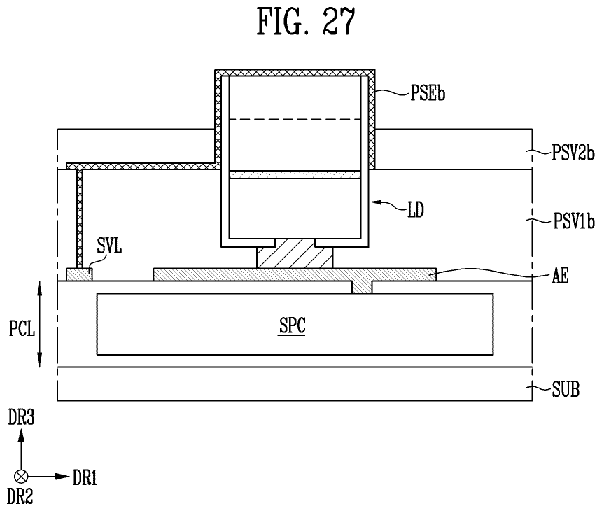

Referring to FIG. 27, the first mask layer PR1b may be removed, and the second passivation layer PSV2b may be formed. The height of the upper surface of the second passivation layer PSV2b may be equal to or lower than the height of the upper surface of the first doped part 21.

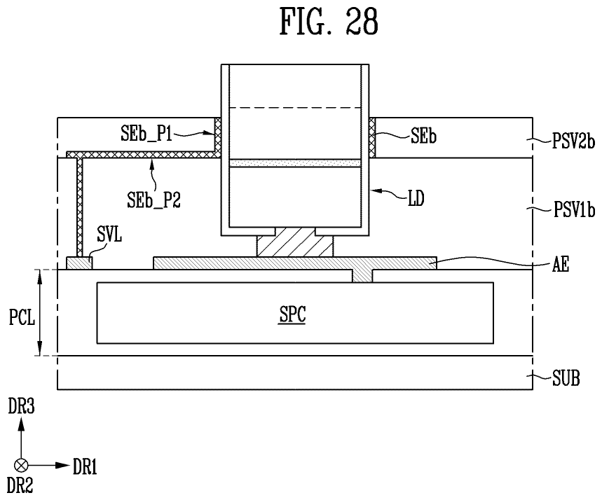

Referring to FIG. 28, an auxiliary electrode SEb, including a first portion SEb_P1 and a second portion SEb_P2, may be formed by etching the preliminary auxiliary electrode PSEb using the second passivation layer PSV2b as a mask. The thickness of the first portion SEb_P1 in the third direction DR3 may be the same as the thickness of the second passivation layer PSV2b in the third direction DR3.

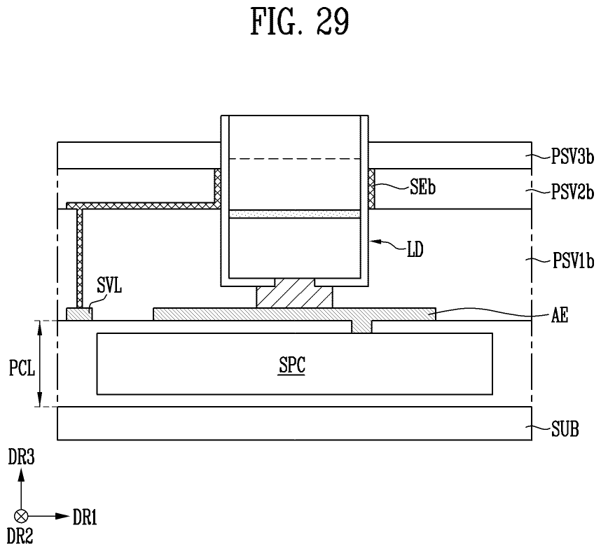

Referring to FIG. 29, a third passivation layer PSV3b may be formed on the second passivation layer PSV2b. The height of the upper surface of the third passivation layer PSV3b may be lower than the height of the upper surface of the light-emitting element LD. The height of the upper surface of the third passivation layer PSV3b may be higher than the height of the upper surface of the first doped part 21.

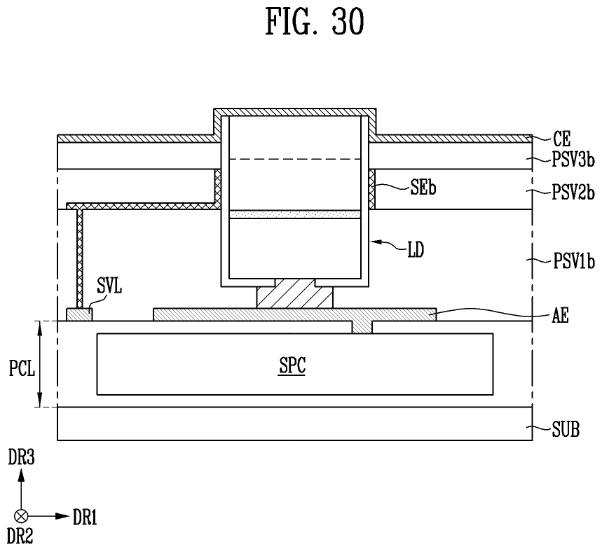

Referring to FIG. 30, the cathode electrode CE may be disposed on the third passivation layer PSV3b and the light-emitting element LD, covering both the third passivation layer PSV3b and the light-emitting element LD. The cathode electrode CE may cover a step difference between the upper surface of the third passivation layer PSV3b and the upper surface of the light-emitting element LD. The cathode electrode CE may be prevented from being disconnected due to the relatively small step difference.

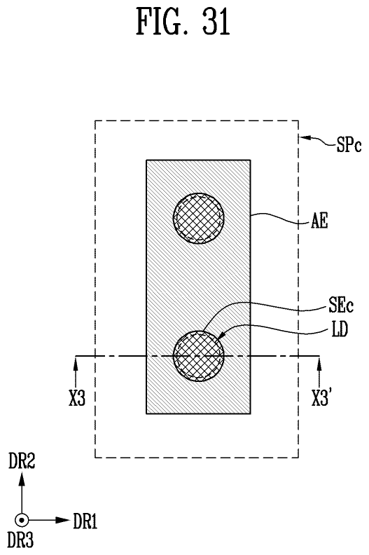

FIG. 31 is a schematic plan view illustrating a third embodiment of a sub-pixel included in the display panel of FIG. 3.

In describing FIG. 31, only the differences from the embodiment described with reference to FIG. 7 will be described, and the omitted parts are replaced with the above descriptions.

Referring to FIG. 31, the sub-pixel SPc may be any one of the first to third sub-pixels SP1, SP2, and SP3 of FIG. 3.

The sub-pixel SPc may include an anode electrode AE, a light-emitting element LD, and an auxiliary electrode SEc.

The auxiliary electrode SEc may surround the side surface of the light-emitting element LD and cover the upper surface of the light-emitting element LD.

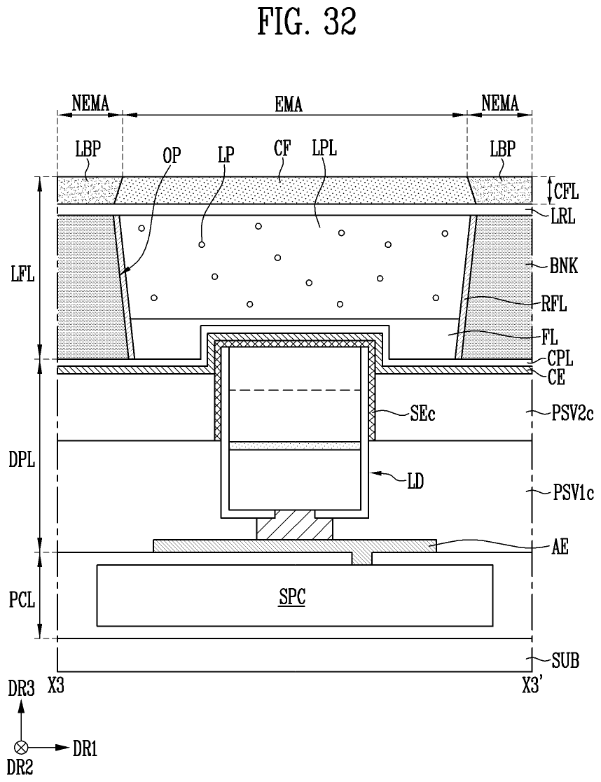

FIG. 32 is a schematic cross-sectional view taken along line X3-X3′ in FIG. 31.

In describing FIG. 32, only the differences from the embodiment described with reference to FIG. 8 will be described, and the omitted parts are replaced with the above descriptions.

Referring to FIGS. 31 and 32, the display element layer DPL may include an anode electrode AE, a light-emitting element LD, first and second passivation layers PSVIc, and PSV2c, an auxiliary electrode SEc, a cathode electrode CE, and a capping layer CPL.

The first passivation layer PSVIc may be disposed on the anode electrode AE and the pixel circuit layer PCL. The light-emitting element LD may be partially buried in the first passivation layer PSVIc. The first passivation layer PSVIc may secure the light-emitting element LD bonded to the anode electrode AE, preventing movement. The first passivation layer PSVIc may include substantially the same material as the first passivation layer PSV1a described with reference to FIG. 8.

The upper surface of the first passivation layer PSVIc may be substantially flat. In an embodiment, the height of the upper surface of the first passivation layer PSVIc may be equal to or higher than the height of the upper surface of the active layer 30.

The auxiliary electrode SEc may cover more of the upper surface of the light-emitting element LD compared to the auxiliary electrode SEa described with reference to FIG. 8. For example, the auxiliary electrode SEc may cover the entire upper surface of the light-emitting element LD and may be in contact (or direct contact) with the entire upper surface of the light-emitting element LD. The auxiliary electrode SEc may be disposed (or interposed) between the cathode electrode CE and the upper surface of the second semiconductor layer 20.

In an embodiment, the auxiliary electrode SEc may be substantially transparent or translucent to meet a selected light transmittance. For example, the auxiliary electrode SEc may include at least one transparent conductive material, such as indium tin oxide (ITO), indium zinc oxide (IZO), zinc oxide (ZnO), indium gallium zinc oxide (IGZO), indium tin zinc oxide (ITZO), and the like. However, the material of the auxiliary electrode SEc is not limited thereto.

The second passivation layer PSV2c may be disposed on the first passivation layer PSV1c. The second passivation layer PSV2c and the first passivation layer PSVIc may include substantially the same (or similar) material.

The upper surface of the second passivation layer PSV2c may be substantially flat. In an embodiment, the height of the upper surface of the second passivation layer PSV2c may be lower than the height of the upper surface of the light-emitting element LD. The light-emitting element LD may partially protrude above the second passivation layer PSV2c. The auxiliary electrode SEc may also partially protrude above the second passivation layer PSV2c.

In an embodiment, the height of the upper surface of the second passivation layer PSV2c may be higher than the height of the upper surface of the first doped part 21. Accordingly, the step difference between the upper surface of the second passivation layer PSV2c and the upper surface of the auxiliary electrode SEc covering the upper surface of the light-emitting element LD may be relatively reduced. The cathode electrode CE may be prevented from being disconnected due to the step difference.

The cathode electrode CE may be disposed on the second passivation layer PSV2c and the auxiliary electrode SEc, covering both the second passivation layer PSV2c and the auxiliary electrode SEc. The cathode electrode CE may be in contact with the auxiliary electrode SEc.

In the sub-pixel SPc according to the third embodiment, the auxiliary electrode SEc may surround the side surface of the light-emitting element LD, cover the upper surface of the light-emitting element LD, and connect to the cathode electrode CE. A voltage applied to the auxiliary electrode SEc (i.e., the second power supply voltage) may cause polarization in the insulating film 40 in contact with the auxiliary electrode SEc. Accordingly, the carriers in the second semiconductor layer 20 may be concentrated toward the center rather than moving to the surface (i.e., side surface) of the second semiconductor layer 20, thereby improving the light emission efficiency of the light-emitting element LD.

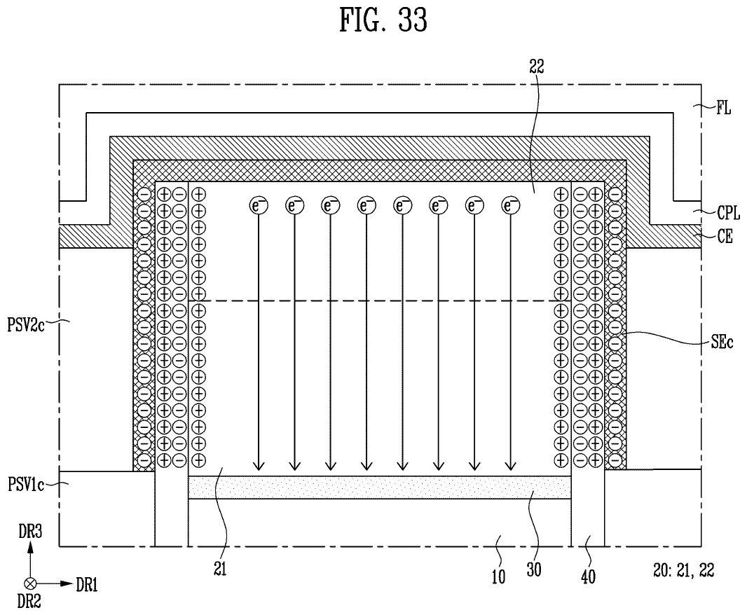

FIG. 33 is an enlarged schematic cross-sectional view of one area of FIG. 32.

Referring to FIGS. 32 and 33, the voltage applied to the auxiliary electrode SEc (i.e., the second power supply voltage) may cause the auxiliary electrode SEc to have a negative polarity. This negative polarity may induce polarization in the insulating film 40. More specifically, a first portion of the insulating film 40 in contact with the auxiliary electrode SEc may have a positive polarity, opposite to the polarity of the auxiliary electrode SEc. A second portion of the insulating film 40, surrounded by the first portion, may have a negative polarity opposite to the polarity of the first portion.

The second portion of the insulating film 40 may be in contact with the second semiconductor layer 20. Extra electrons may be present in the second semiconductor layer 20, which is an n-type semiconductor layer doped with an n-type dopant. Since the second portion of the insulating film 40 has a negative polarity, a repulsive force may exist between the second portion of the insulating film 40 and the extra electrons. Accordingly, the extra electrons may be distributed more in the center than on the surface (i.e., side surface) of the second semiconductor layer 20. The extra electrons may be substantially absent from the surface (i.e., side surface) of the second semiconductor layer 20, or may be relatively few in number. As shown in FIG. 33, the surface (i.e., side surface) of the second semiconductor layer 20 in contact with the second portion of the insulating film 40 may have a positive polarity due to the deficiency of electrons.

As the extra electrons distributed more in the center rather than on the surface (i.e., side surface) of the second semiconductor layer 20, the path of electron movement in the second semiconductor layer 20 may also be formed in the center of the second semiconductor layer 20. Accordingly, the electrons in the second semiconductor layer 20 may be concentrated toward the center instead of moving to the surface (i.e., side surface) of the second semiconductor layer 20. The electrons in the second semiconductor layer 20 may be more effectively provided to the active layer 30, improving the light emission efficiency of the light-emitting element LD.

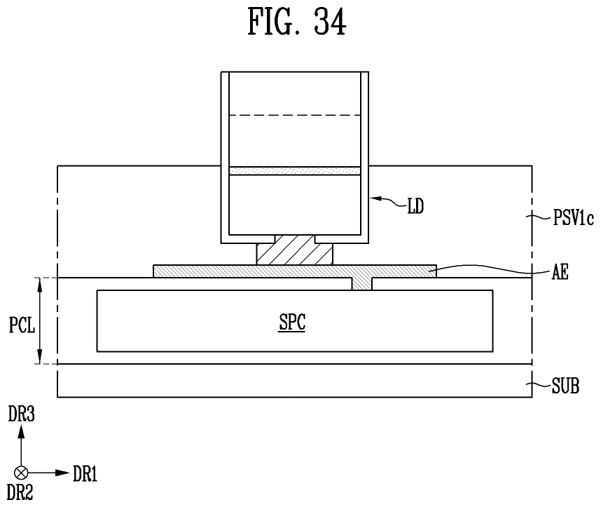

FIGS. 34 to 40 are schematic cross-sectional views illustrating a method of manufacturing the sub-pixel of FIG. 32.

Referring to FIG. 34, after bonding the light-emitting element LD to the anode electrode AE, the first passivation layer PSVIc may be formed. In this step, the light-emitting element LD may be partially buried in the first passivation layer PSVIc. The height of the upper surface of the first passivation layer PSVIc may be equal to or higher than the height of the upper surface of the active layer 30.

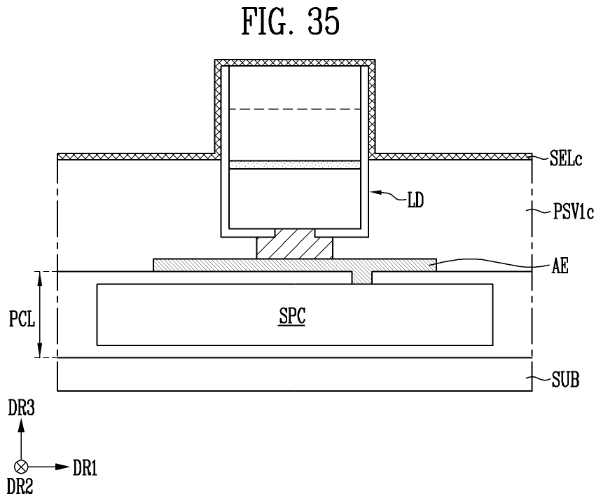

Referring to FIG. 35, an auxiliary electrode layer SELc, covering both the first passivation layer PSVIc and the light-emitting element LD, may be formed. The auxiliary electrode layer SELc may cover the entire first passivation layer PSVIc and the light-emitting element LD. The auxiliary electrode layer SELc may also cover the portion of the light-emitting element LD protruding above the first passivation layer PSVIc.

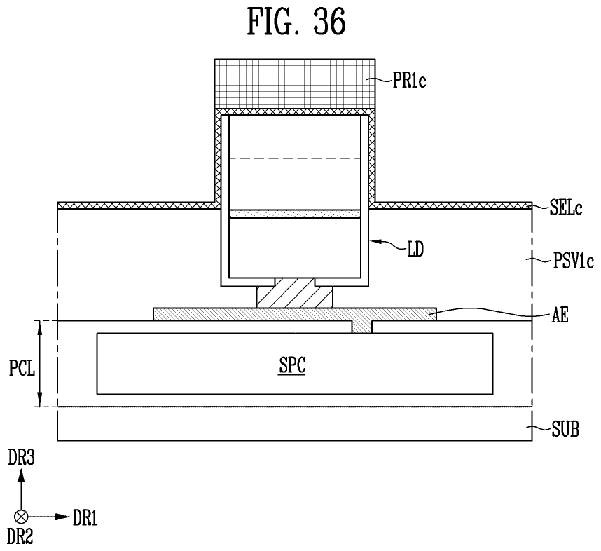

Referring to FIG. 36, a first mask layer PR1c may be formed on the auxiliary electrode layer SELc, overlapping the upper surface of the light-emitting element LD. The first mask layer PR1c may include, for example, a photoresist material.

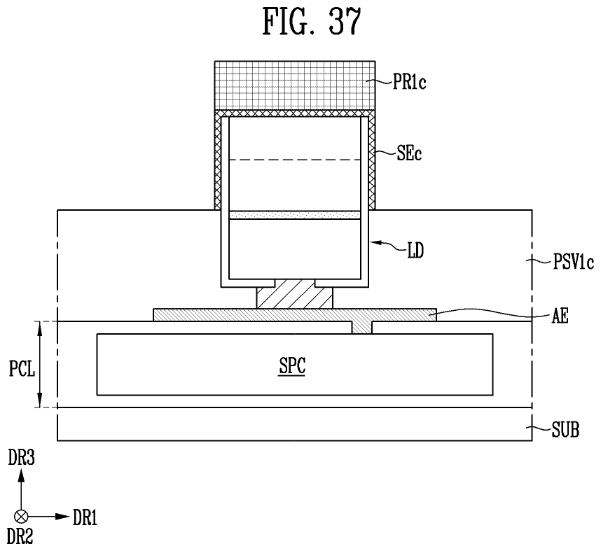

Referring to FIG. 37, an auxiliary electrode SEc may be formed by etching the auxiliary electrode layer SELc using the first mask layer PR1c as a mask. In this step, a portion of the auxiliary electrode layer SELc covering the upper surface of the first passivation layer PSVIc may be removed by etching. The auxiliary electrode SEc may cover the portion of the light-emitting element LD protruding above the first passivation layer PSVIc as a whole (or entirely).

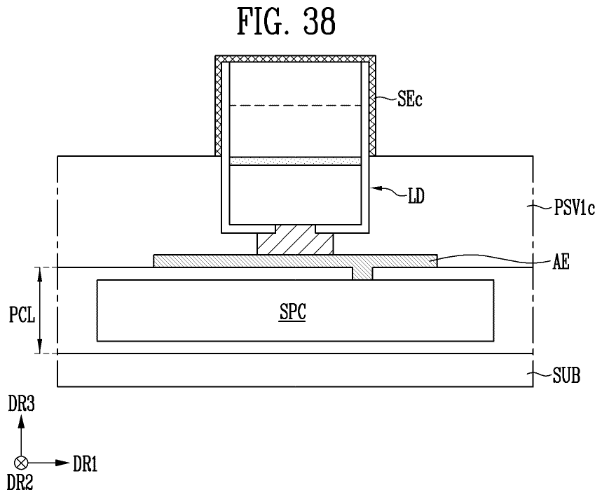

Referring to FIG. 38, the first mask layer PR1c may be removed.

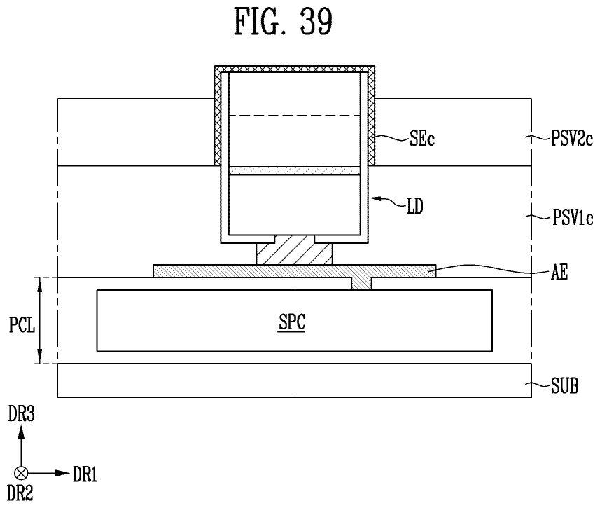

Referring to FIG. 39, a second passivation layer PSV2c may be formed on the first passivation layer PSV1c. The height of the upper surface of the second passivation layer PSV2c may be lower than the height of the upper surface of the light-emitting element LD. The height of the upper surface of the second passivation layer PSV2c may be higher than the height of the upper surface of the first doped part 21.

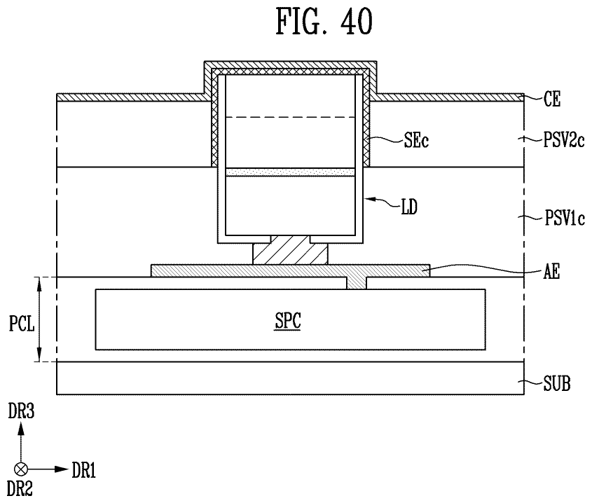

Referring to FIG. 40, the cathode electrode CE may be formed on both the second passivation layer PSV2c and the auxiliary electrode SEc, covering both the second passivation layer PSV2c and the auxiliary electrode SEc. The cathode electrode CE may cover a step difference between the upper surface of the second passivation layer PSV2a and the upper surface of auxiliary electrode SEc covering the upper surface of the light-emitting element LD. The cathode electrode CE may be prevented from being disconnected due to the relatively small step difference.

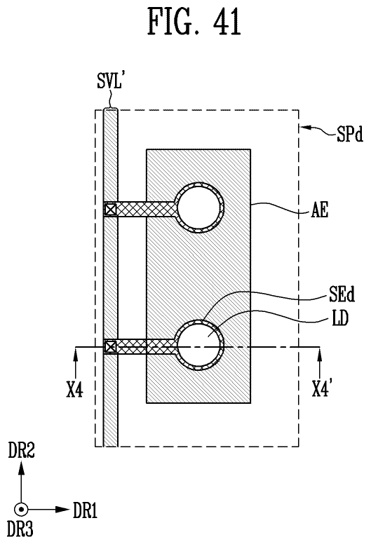

FIG. 41 is a schematic plan view illustrating a fourth embodiment of a sub-pixel included in the display panel of FIG. 3.

In describing FIG. 41, only the differences from the embodiment described with reference to FIG. 7 will be described, and the omitted parts are replaced with the above descriptions.

Referring to FIG. 41, a sub-pixel SPd may be any one of the first to third sub-pixels SP1, SP2, and SP3 of FIG. 3.

The sub-pixel SPd may include an anode electrode AE, a light-emitting element LD, an auxiliary electrode SEd, and an auxiliary voltage line SVL′.

The auxiliary electrode SEd may surround the side surface of the light-emitting element LD. The auxiliary electrode SEd may extend from the light-emitting element LD toward the auxiliary voltage line SVL′ and may partially overlap the auxiliary voltage line SVL′. The auxiliary electrode SEd may be connected to the auxiliary voltage line SVL′ through a contact hole, and may receive an auxiliary voltage through the auxiliary voltage line SVL′.

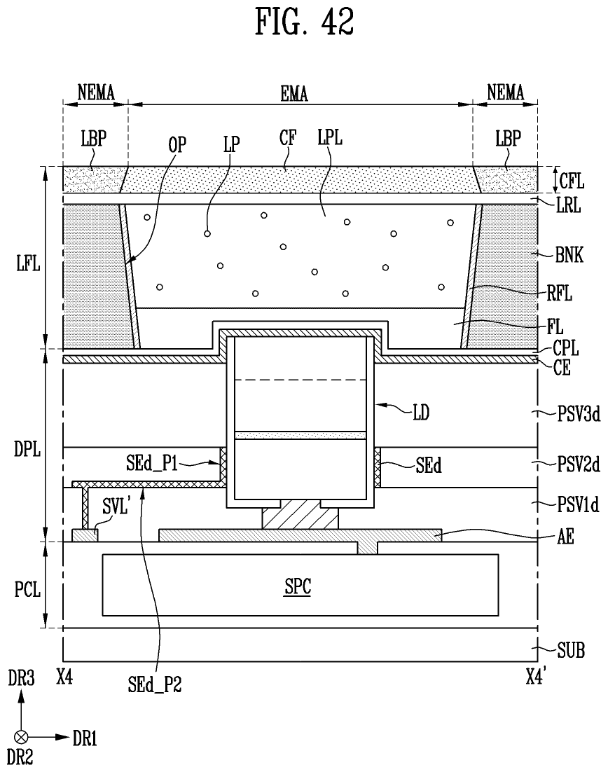

FIG. 42 is a schematic cross-sectional view taken along line X4-X4′ in FIG. 41.

In describing FIG. 42, only the differences from the embodiment described with reference to FIG. 8 will be described, and the omitted parts are replaced with the above descriptions.

Referring to FIGS. 41 and 42, the display element layer DPL may include an anode electrode AE, an auxiliary voltage line SVL′, a light-emitting element LD, first to third passivation layers PSV1d, PSV2d, and PSV3d, an auxiliary electrode SEd, a cathode electrode CE, and a capping layer CPL.

The auxiliary voltage line SVL′ may be spaced apart from the anode electrode AE. However, the embodiments are not limited thereto. For example, the auxiliary voltage line SVL′ may be connected to the anode electrode AE, or may be integrally formed with the anode electrode AE. The auxiliary voltage line SVL′ may be disposed in the same layer as the anode electrode AE. However, the embodiments are not limited thereto. For example, the auxiliary voltage line SVL′ may be disposed on any one of the insulating layers forming the pixel circuit layer PCL.

The first passivation layer PSV1d may be disposed on the anode electrode AE, the auxiliary voltage line SVL′, and the pixel circuit layer PCL. The light-emitting element LD may be partially buried in the first passivation layer PSV1d. The first passivation layer PSV1d may secure the light-emitting element LD bonded to the anode electrode AE so that it does not move. The first passivation layer PSV1d may include substantially the same material as the first passivation layer PSV1a described with reference to FIG. 8.

The upper surface of the first passivation layer PSV1d may be substantially flat. In an embodiment, the height of the upper surface of the first passivation layer PSV1d may be lower than the height of the lower surface of the active layer 30.

The auxiliary electrode SEd may include a first portion SEd_P1 and a second portion SEd_P2.

The first portion SEd_P1 may surround the side surface of the light-emitting element LD. For example, the first portion SEd_P1 may surround the side surface of the first semiconductor layer 10 of the light-emitting element LD. An insulating film 40 may be disposed (or interposed) between the first portion SEd_P1 and the light-emitting member EST, and the first portion SEd_P1 may be in contact (or direct contact) with the insulating film 40. The first portion SEd_P1 may be disposed below the lower surface of the active layer 30. In an embodiment, the first portion SEd_P1 may be disposed on the first passivation layer PSV1d.

The second portion SEd_P2 may extend from the first portion SEd_P1. For example, the second portion SEd_P2 may extend from the first portion SEd_P1 in a direction opposite to the first direction DR1. The second portion SEd_P2 may not be in contact (or direct contact) with the insulating film 40. The second portion SEd_P2 may partially overlap the auxiliary voltage line SVL′. The second portion SEd_P2 may be connected to the auxiliary voltage line SVL′ via contact holes. In an embodiment, the second portion SEd_P2 may extend along the upper surface of the first passivation layer PSV1d from the first portion SEd_P1.

In an embodiment, the auxiliary electrode SEd may reflect incident light, thereby improving light emission efficiency. For example, the auxiliary electrode SEd may include a light-reflective conductive material. For example, the auxiliary electrode SEd may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

The second passivation layer PSV2d may be disposed on the first passivation layer PSV1d. The second passivation layer PSV2d and the first passivation layer PSV1d may include substantially the same (or, similar) material.

The upper surface of the second passivation layer PSV2d may be substantially flat. In an embodiment, the height of the upper surface of the second passivation layer PSV2b may be equal to or lower than the height of the lower surface of the active layer 30.

In an embodiment, the thickness of the second passivation layer PSV2d in the third direction DR3 may be the same as the thickness of the first portion SEd_P1 in the third direction DR3.

The third passivation layer PSV3d may be disposed on the second passivation layer PSV2d. The third passivation layer PSV3d and the first passivation layer PSV1d may include substantially the same (or similar) material.

The upper surface of the third passivation layer PSV3d may be substantially flat. In an embodiment, the height of the upper surface of the third passivation layer PSV3d may be lower than the height of the upper surface of the light-emitting element LD. The light-emitting element LD may partially protrude above the third passivation layer PSV3d.

In an embodiment, the height of the upper surface of the third passivation layer PSV3d may be higher than the height of the upper surface of the first doped part 21. Accordingly, the step difference between the upper surface of the third passivation layer PSV3d and the upper surface of the light-emitting element LD may be relatively reduced. The cathode electrode CE may be prevented from being disconnected due to the relatively small step difference.

The cathode electrode CE may be disposed on both the third passivation layer PSV3d and the light-emitting element LD, covering both the third passivation layer PSV3d and the light-emitting element LD. In an embodiment, the cathode electrode CE may be spaced apart from the auxiliary electrode SEd.

In the sub-pixel SPd according to the fourth embodiment, an auxiliary electrode SEd may surround the side surface of the light-emitting element LD and may be connected to the auxiliary voltage line SVL′. The auxiliary voltage line SVL′ may transmit an auxiliary voltage to the auxiliary electrode SEd. The auxiliary voltage applied to the auxiliary electrode SEd may cause polarization in the insulating film 40 in contact with the auxiliary electrode SEd. Accordingly, the carriers in the first semiconductor layer 10 may concentrate toward the center rather than moving to the surface (i.e., side surface) of the first semiconductor layer 10. This may improve the light emission efficiency of the light-emitting element LD.

In an embodiment, the auxiliary voltage transmitted through the auxiliary voltage line SVL′ may be applied at various levels to concentrate the carriers in the second semiconductor layer 10 toward the center by generating polarization in the insulating film 40 in contact with the auxiliary electrode SEd. For example, the auxiliary voltage may have the same (or similar) level as the voltage applied to the anode electrode AE.

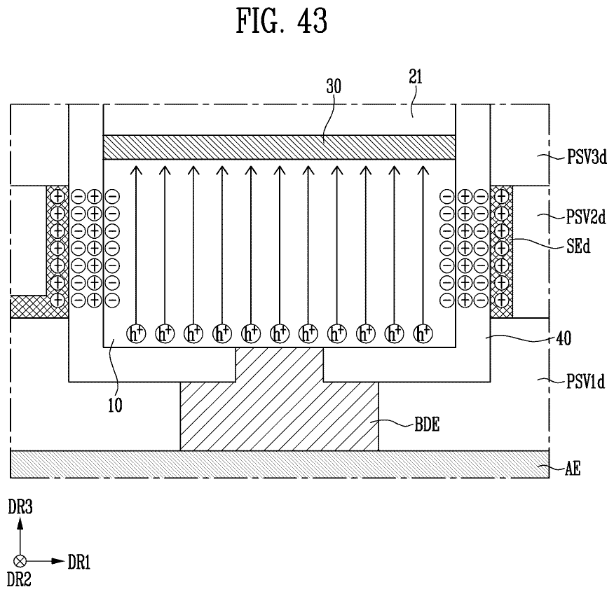

FIG. 43 is an enlarged schematic cross-sectional view of one area of FIG. 42.

Referring to FIGS. 42 and 43, the auxiliary voltage applied to the auxiliary electrode SEd may cause the auxiliary electrode SEd to have a positive polarity. This positive polarity may induce polarization in the insulating film 40. More specifically, a first portion of the insulating film 40 in contact with the auxiliary electrode SEd may have a negative polarity, opposite to the polarity of the auxiliary electrode SEd. A second portion of the insulating film 40, surrounded by the first portion, may have a positive polarity opposite to the polarity of the first portion.

The second portion of the insulating film 40 may be in contact with the first semiconductor layer 10. Extra holes may be present in the first semiconductor layer 10, which is a p-type semiconductor layer doped with an p-type dopant. Due to the positive polarity of the second portion of the insulating film 40, a repulsive force may exist between the second portion of the insulating film 40 and the extra holes. Accordingly, the extra holes may be distributed more in the center rather than on the surface (i.e., side surface) of the first semiconductor layer 10. The extra holes may be substantially absent from the surface (i.e., side surface) of the first semiconductor layer 10, or may be relatively few in number. As shown in FIG. 43, the surface (i.e., side surface) of the first semiconductor layer 10 in contact with the second portion of the insulating film 40 may have a negative polarity due to the deficiency of holes.

As the extra holes are distributed more in the center than on the surface (i.e., side surface) of the first semiconductor layer 10, the path of movement of the holes in the first semiconductor layer 10 may also be formed in the center of the first semiconductor layer 10. Accordingly, the holes in the first semiconductor layer 10 may be concentrated toward the center rather than moving to the surface (i.e., side surface) of the first semiconductor layer 10. The holes in the first semiconductor layer 10 may be more effectively provided to the active layer 30. This may improve the light emission efficiency of the light-emitting element LD.

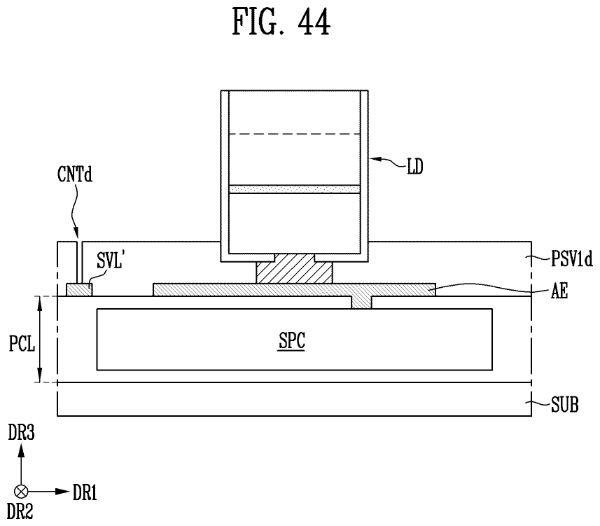

FIGS. 44 to 52 are schematic cross-sectional views illustrating a method of manufacturing the sub-pixel of FIG. 42.

Referring to FIG. 44, after bonding the light-emitting element LD to the anode electrode AE, the first passivation layer PSV1d may be formed. A contact hole CNTd may be formed through the first passivation layer PSV1d to expose the auxiliary voltage line SVL′. In this step, the light-emitting element LD may be partially buried in the first passivation layer PSV1d. The height of the upper surface of the first passivation layer PSV1d may be lower than the height of the lower surface of the active layer 30.

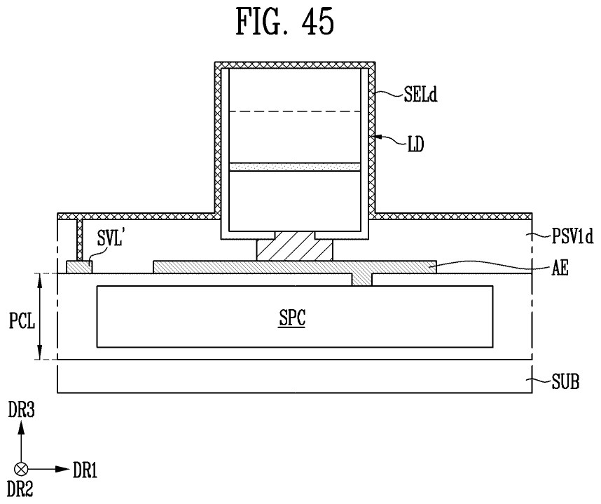

Referring to FIG. 45, an auxiliary electrode layer SELd covering the first passivation layer PSV1d and the light-emitting element LD may be formed. The auxiliary electrode layer SELd may cover both the first passivation layer PSV1d and the light-emitting element LD as a whole (or entirely). The auxiliary electrode layer SELd may be connected to the auxiliary voltage line SVL′ via contact hole CNTd. The auxiliary electrode layer SELd may cover the portion of the light-emitting element LD that protrudes above the first passivation layer PSV1d as a whole.

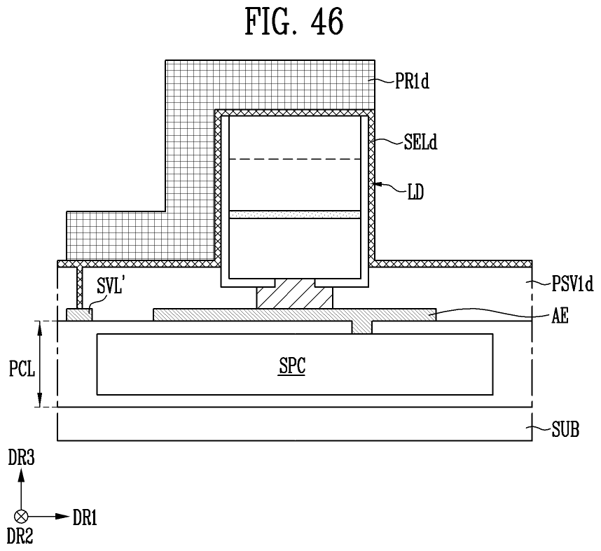

Referring to FIG. 46, a first mask layer PR1d may be formed, extending from the upper surface of the light-emitting element LD to the contact hole CNTd. The first mask layer PR1d may include, for example, a photoresist material.

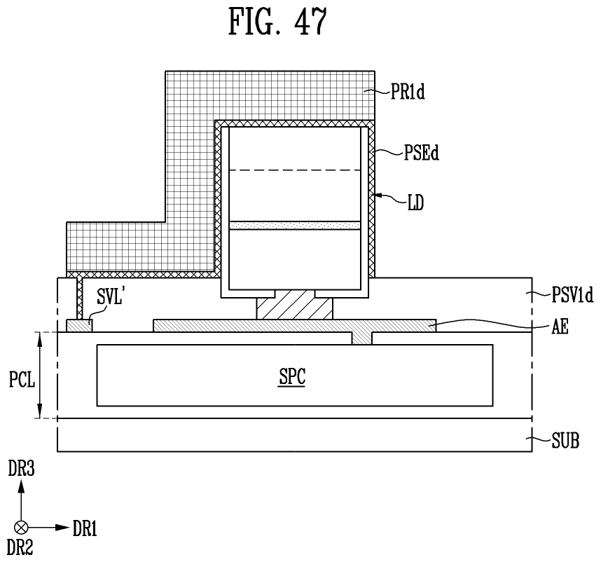

Referring to FIG. 47, a preliminary auxiliary electrode PSEd may be formed by etching the auxiliary electrode layer SELd using the first mask layer PR1d as a mask. In this step, a portion of the auxiliary electrode layer SELd not overlapping the first mask layer PR1d may be removed by etching. The preliminary auxiliary electrode PSEd may entirely cover the portion of the light-emitting element LD protruding above the first passivation layer PSV1d and may be connected to the auxiliary voltage line SVL′ via contact holes CNTd. The preliminary auxiliary electrode PSEd may have substantially the same in-plane shape as the auxiliary electrode SEd described with reference to FIG. 38, except that it covers the upper surface of the light-emitting element LD.

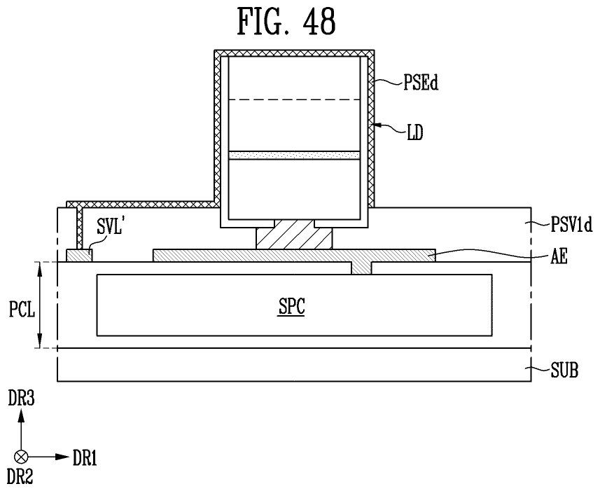

Referring to FIG. 48, the first mask layer PR1d may be removed.

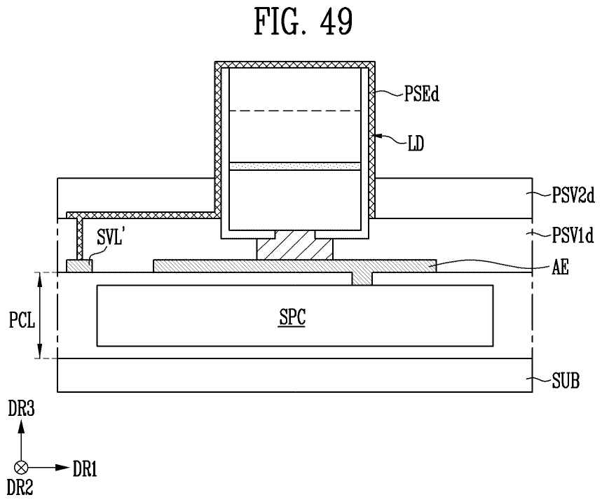

Referring to FIG. 49, a second passivation layer PSV2d may be formed on the first passivation layer PSV1d. The height of the upper surface of the second passivation layer PSV2d may be equal to or lower than the height of the lower surface of the active layer 30.

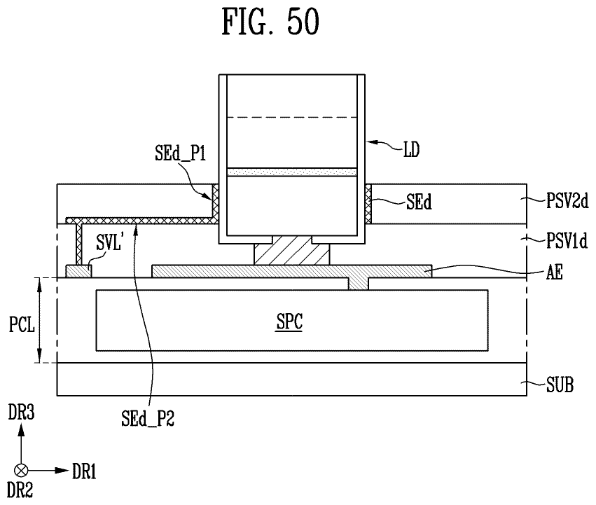

Referring to FIG. 50, an auxiliary electrode Sed, including a first portion SEd_P1 and a second portion SEd_P2, may be formed by etching a preliminary auxiliary electrode PSEd using the second passivation layer PSV2d as a mask. The thickness of the first part SEd_P1 in the third direction DR3 may be the same as the thickness of the second passivation layer PSV2d in the third direction DR3.

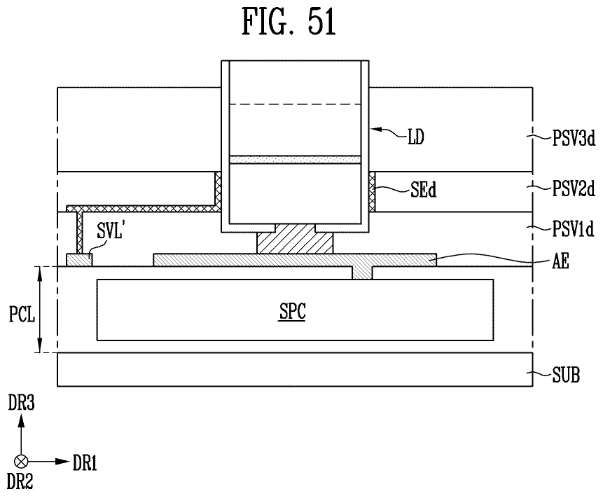

Referring to FIG. 51, a third passivation layer PSV3d may be formed on the second passivation layer PSV2d. The height of the upper surface of the third passivation layer PSV3d may be lower than the height of the upper surface of the light-emitting element LD. The height of the upper surface of the third passivation layer PSV3d may be higher than the height of the upper surface of the first doped part 21.

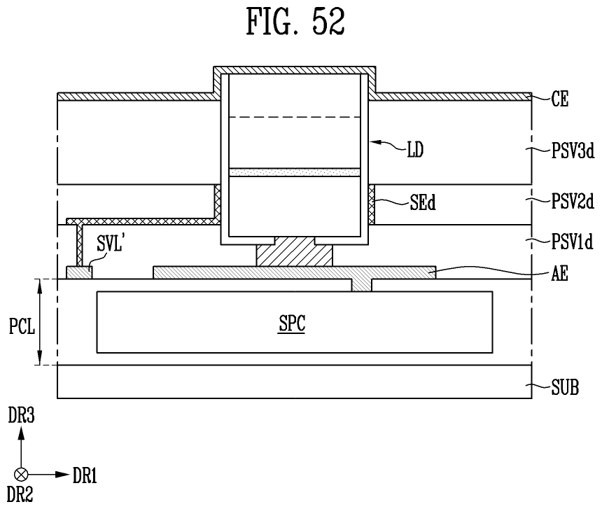

Referring to FIG. 52, the cathode electrode CE may be disposed on the third passivation layer PSV3d and the light-emitting element LD, such that it covers the third passivation layer PSV3d and the light-emitting element LD. The cathode electrode CE may cover a step difference between the upper surface of the third passivation layer PSV3d and the upper surface of the light-emitting element LD. The cathode electrode CE may be prevented from being disconnected due to the relatively small step difference.

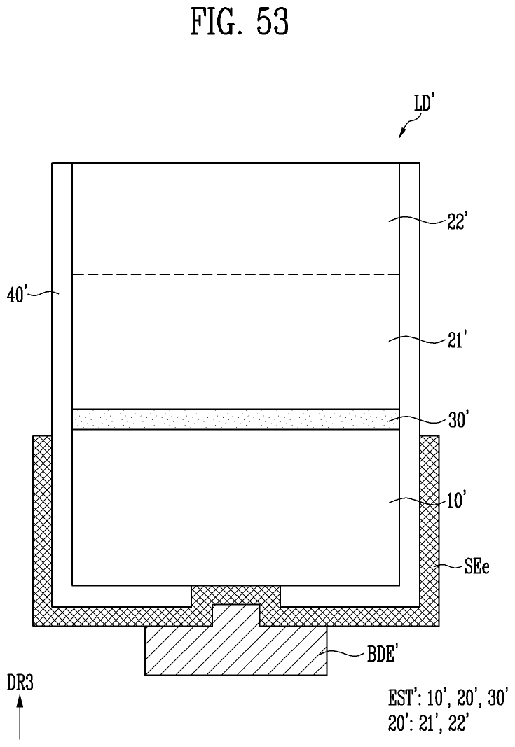

FIG. 53 is a schematic cross-sectional view illustrating a light-emitting element according to another embodiment.

Referring to FIG. 53, the light-emitting element LD′ may include a bonding electrode BDE′, an auxiliary electrode SEe, a light-emitting member EST′, and an insulating film 40. The light-emitting member EST′ may include a first semiconductor layer 10′, a second semiconductor layer 20′, and an active layer 30′. The light-emitting element LD′ may be implemented as a vertical light-emitting member in which the bonding electrode BDE′, the auxiliary electrode SEe; the first semiconductor layer 10′, the active layer 30′, and the second semiconductor layer 20′ are stacked sequentially along the third direction DR3.

The first semiconductor layer 10′ may function similarly to the first semiconductor layer 10 described with reference to FIG. 6. For example, the first semiconductor layer 10′ may provide holes.

The second semiconductor layer 20′ may be disposed on the first semiconductor layer 10′. The second semiconductor layer 20′ may be configured similarly to the second semiconductor layer 20′ described with reference to FIG. 6. For example, the second semiconductor layer 20′ may provide electrons.

In an embodiment, the second semiconductor layer 20′ may include a first doped part 21′ and a second doped part 22′ that are sequentially stacked along the third direction DR3. The first doped part 21′ may be a region doped with a relatively high concentration of dopant, while the second doped part 22′ may be a region doped with a relatively low concentration of dopant, or may be a region substantially undoped. For example, the first average doping concentration of the dopant in the first doped part 21′ may be greater than the second average doping concentration of the dopant in the second doped part 22′.

The active layer 30′ may be disposed between the first semiconductor layer 10′ and the second semiconductor layer 20′. The active layer 30′ may be configured similarly to the active layer 30 described with reference to FIG. 6. For example, the active layer 30′ may provide a region where electrons and holes recombine, and as these electrons and holes recombine in the active layer 30′, they may transition to lower energy levels and emit light at a corresponding wavelength.

The insulating film 40′ may cover at least part of the side surface of the light-emitting member EST′. For example, the insulating film 40′ may cover the side surface of the light-emitting member EST′ and a portion of the lower surface of the light-emitting member EST′. The insulating film 40′ may prevent electrical shorts that may occur in the case where the active layer 30′ comes into contact with conductive materials other than the first and second semiconductor layers 10′ and 20′. In an embodiment, the insulating film 40′ may expose the upper surface of the light-emitting member EST′.

The auxiliary electrode SEe may be connected to (or be in contact with) a portion of the lower surface of the first semiconductor layer 10′ that is not covered by the insulating film 40′. The auxiliary electrode SEe may surround the side surface of the first semiconductor layer 10′ below the active layer 30′. The insulating film 40′ may be disposed between the auxiliary electrode SEe and the side surface of the first semiconductor layer 10′.

In an embodiment, the auxiliary electrode SEe may reflect incident light, thereby improving light emission efficiency. For example, the auxiliary electrode SEe may include a light-reflective conductive material. For example, the auxiliary electrode SEe may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

The bonding electrode BDE′ may be disposed below the auxiliary electrode SEe. The bonding electrode BDE′ may be connected to the auxiliary electrode SEe. The bonding electrode BDE′ may be connected to the first semiconductor layer 10′ through the auxiliary electrode SEe. In an embodiment, the bonding electrode BDE′ may include a eutectic metal.

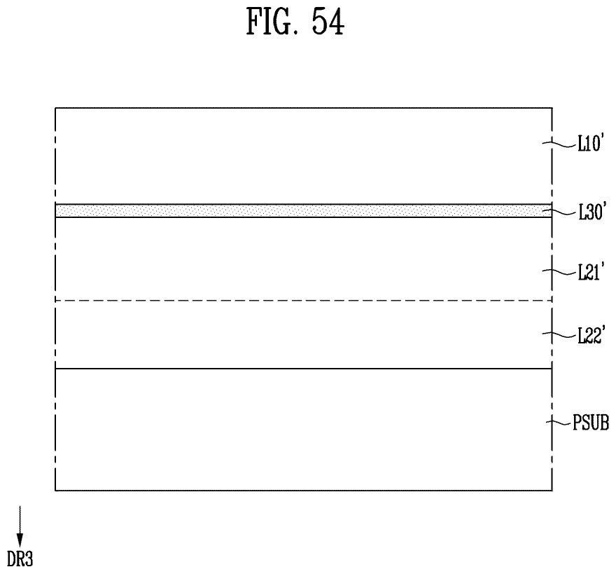

FIGS. 54 to 61 are schematic cross-sectional views illustrating a method of manufacturing the light-emitting element of FIG. 53.

Referring to FIG. 54, the second doped layer L22′, the first doped layer L21′, the active material layer L30′, and the first semiconductor formation layer L10′ may be formed on a surface of the growth substrate PSUB in sequence. The second doped layer L22′, the first doped layer L21′, the active material layer L30′, and the first semiconductor formation layer L10′ may be stacked sequentially along a direction opposite to the third direction DR3.

The second doped layer L22′, the first doped layer L21′, the active material layer L30′, and the first semiconductor formation layer L10′ may be formed by various semiconductor formation processes known in the art. The growth substrate PSUB may include a material (for example, sapphire, etc.) suitable for performing such semiconductor formation processes.

The second doped layer L22′ and the second doped part 22′ may include the same material. The first doped layer L21′ and the first doped part 21′ may include the same material. The active material layer L30′ and the active layer 30′ may include the same material. The first semiconductor formation layer L10′ and the first semiconductor layer 10′ may include the same material.

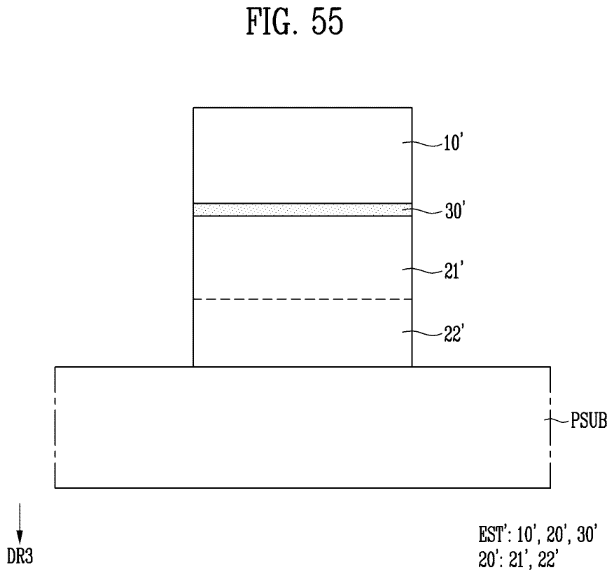

Referring to FIG. 55, the second doped layer L22′, the first doped layer L21′, the active material layer L30′, and the first semiconductor formation layer L10′ may be etched to form a light-emitting member EST′.

The light-emitting member EST′ may include a first semiconductor layer 10′ formed by etching a first semiconductor forming layer L10′, an active layer 30′ formed by etching an active material layer L30′, a first doped part 21′ formed by etching a first doped layer L21′, and a second doped part 22′ formed by etching a second doped layer L22′.

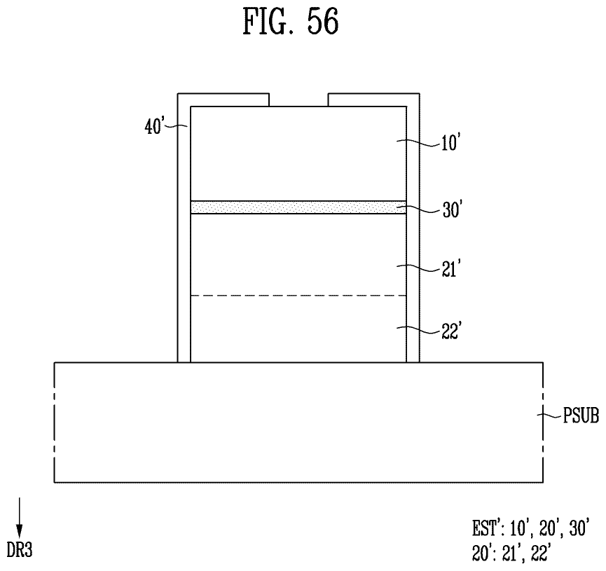

Referring to FIG. 56, an insulating film 40′ may be formed. The insulating film 40′ may be patterned by various methods known in the art to cover at least a side surface of the light-emitting member EST′, while exposing at least a portion of a surface of the first semiconductor layer 10′.

Referring to FIG. 57, a first mask layer PR1′ may be formed on a surface of the growth substrate PSUB on which the light-emitting member EST′ is disposed. The first mask layer PR1′ may include, for example, a photoresist material. The light-emitting member EST′ and the insulating film 40′ may be partially buried in the first mask layer PR1′.

In this step, the first mask layer PR1′ may surround the side surface of the second semiconductor layer 20′ and the side surface of the active layer 30′. The first mask layer PR1′ may be provided to partially surround only the side surface of the first semiconductor layer 10′ adjacent to the active layer 30′, or may not surround any side surface of the first semiconductor layer 10′.

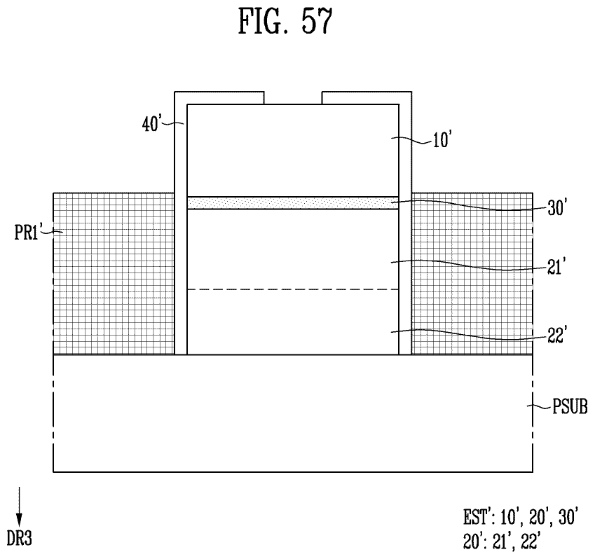

Referring to FIG. 58, an auxiliary electrode layer SELe may be formed. The auxiliary electrode layer SELe may be formed entirely on a surface of the growth substrate PSUB. The auxiliary electrode layer SELe may cover the protruding light-emitting member EST′ and insulating film 40′ without being buried in the first mask layer PR1′.

The auxiliary electrode layer SELe may be in contact with the exposed first semiconductor layer 10′ without being covered by the insulating film 40′. Further, the auxiliary electrode layer SELe may surround the side surface of the first semiconductor layer 10′.

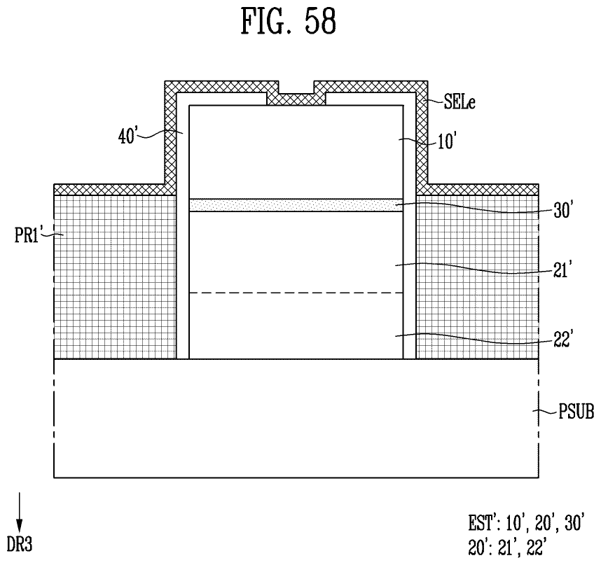

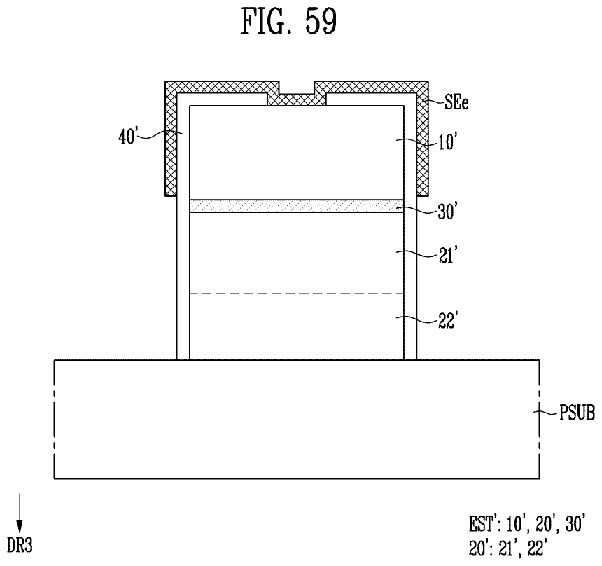

Referring to FIG. 59, the first mask layer PR1′ may be removed. As the first mask layer PR1′ is removed, a portion of the auxiliary electrode layer SELe covering the first mask layer PR1′ may also be removed. Accordingly, the auxiliary electrode SEe may be formed.

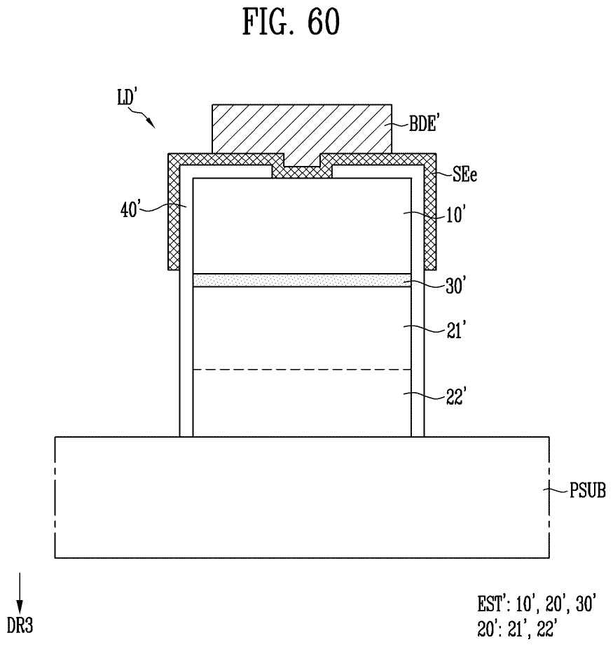

Referring to FIG. 60, a bonding electrode BDE′ may be formed. The bonding electrode BDE′ may be formed, for example, by an etch process using a photoresist material as a mask.

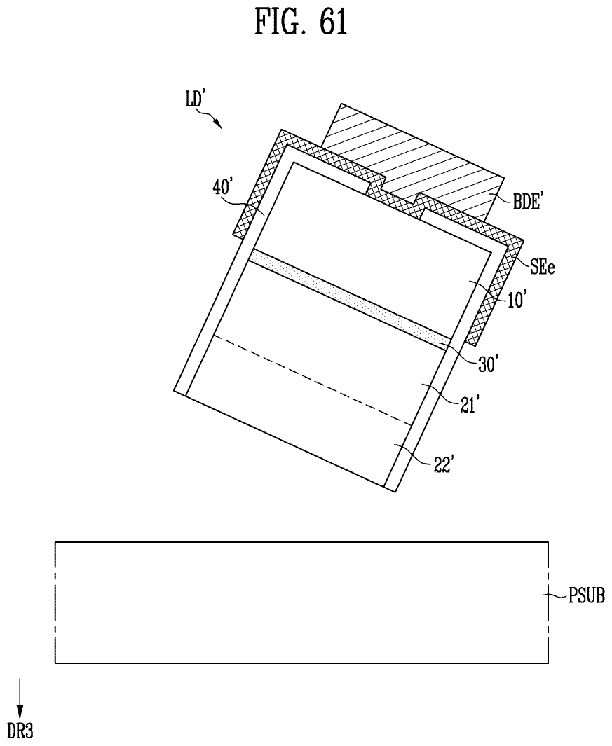

Referring to FIG. 61, the light-emitting element LD′ may be separated from the growth substrate PSUB. The separated light-emitting element LD′ may be provided to a sub-pixel.

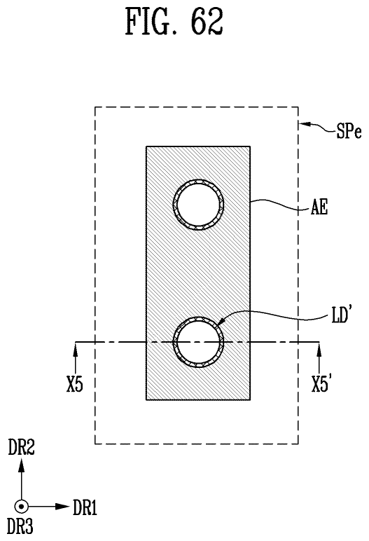

Hereinafter, with reference to FIGS. 62 to 64, sub-pixels SPe that include the light-emitting element LD′ described with reference to FIG. 53 will be described.

FIG. 62 is a schematic plan view illustrating a fifth embodiment of a sub-pixel included in the display panel of FIG. 3.

In describing FIG. 62, only the differences from the embodiment described with reference to FIG. 7 will be described, and the omitted parts are replaced with the above descriptions.

Referring to FIG. 62, a sub-pixel SPe may be any one of the first to third sub-pixels SP1, SP2, and SP3 of FIG. 3.

The sub-pixel SPe may include an anode electrode AE, and a light-emitting element LD′.

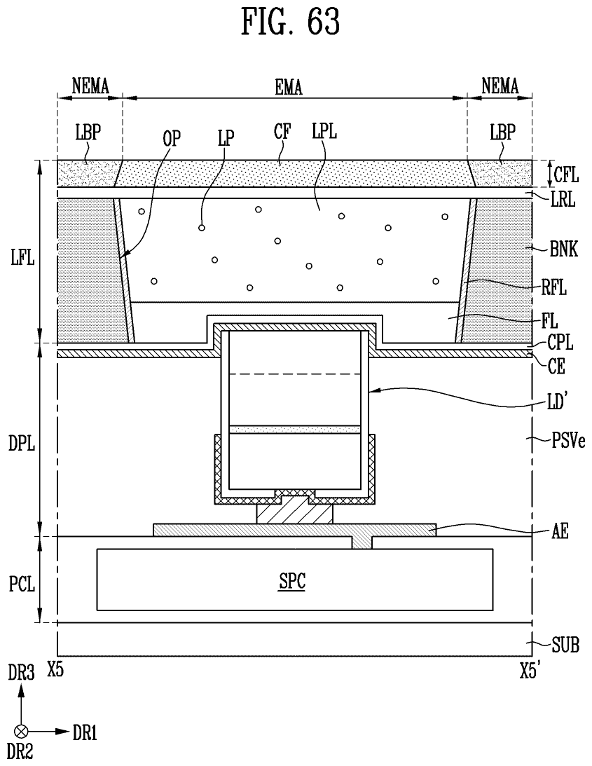

FIG. 63 is a schematic cross-sectional view taken along line X5-X5′ in FIG. 62.

In describing FIG. 63, only the differences from the embodiment described with reference to FIG. 8 will be described, and the omitted parts are replaced with the above descriptions.

Referring to FIGS. 62 and 63, the display element layer DPL may include an anode electrode AE, a light-emitting element LD′, a passivation layer PSVe, a cathode electrode CE, and a capping layer CPL.

The light-emitting element LD′ may be disposed on the anode electrode AE. The bonding electrode BDE′ of the light-emitting element LD′ may be bonded to the anode electrode AE. Through the bonding electrode BDE′ and auxiliary electrode SEe, the anode electrode AE and the first semiconductor layer 10′ may be electrically connected.

The passivation layer PSVe may be disposed on the anode electrode AE and the pixel circuit layer PCL. The light-emitting element LD′ may be partially buried in the passivation layer PSVe. The passivation layer PSVe may secure the light-emitting element LD′ bonded to the anode electrode AE, preventing movement. The passivation layer PSVe may include substantially the same material as the first passivation layer PSV1a described with reference to FIG. 8.

The upper surface of the passivation layer PSVe may be substantially flat. In an embodiment, the height of the upper surface of the passivation layer PSVe may be higher than the height of the upper surface of the first doped part 21′. Accordingly, the step difference between the upper surface of the passivation layer PSVe and the upper surface of the light-emitting element LD′ may be relatively reduced. The cathode electrode CE may be prevented from being disconnected due to the step difference.

The cathode electrode CE may be disposed on the third passivation layer PSVe and the light-emitting element LD′, covering the passivation layer PSVe and the light-emitting element LD′. The cathode electrode CE may be connected to the second semiconductor layer 20′. For example, the cathode electrode CE may contact (or directly contact) the upper surface of the second semiconductor layer 20′. Through the cathode electrode CE, a second power supply voltage applied to the second power supply voltage node VSSN may be transferred to the second semiconductor layer 20′.

In the sub-pixel SPe according to a fifth embodiment, the auxiliary electrode SEe may surround a side surface of the first semiconductor layer 10′ and may be connected to the anode electrode AE via a bonding electrode BDE′. By the voltage applied to the auxiliary electrode SEe (i.e., the voltage applied to the anode electrode AE), polarization may occur in the insulating film 40′ that contacts the auxiliary electrode SEe. Accordingly, the carriers in the first semiconductor layer 10′ may be concentrated toward the center, rather than moving to the surface (i.e., side surface) of the first semiconductor layer 10′. This may improve the light emission efficiency of the light-emitting element LD′.

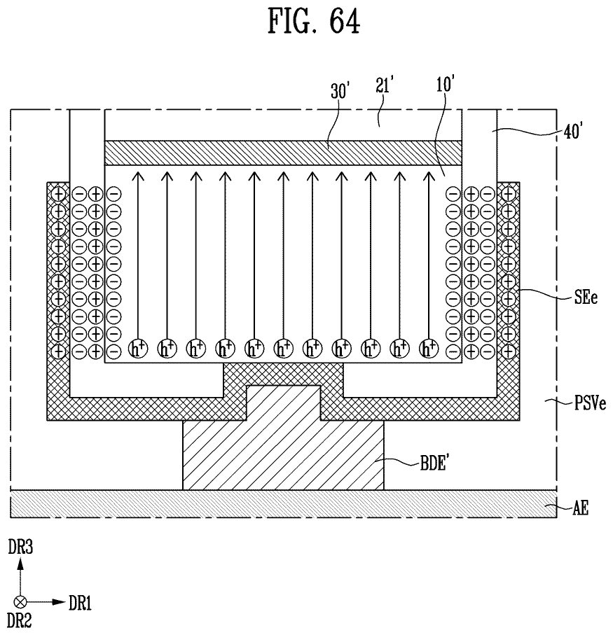

FIG. 64 is an enlarged schematic cross-sectional view of an area of FIG. 63.

Referring to FIGS. 63 and 64, the voltage applied to the auxiliary electrode SEe (i.e., the voltage applied to the anode electrode AE) may cause the auxiliary electrode SEe to have a positive polarity. This positive polarity may induce polarization in the insulating film 40. More specifically, a first portion of the insulating film 40 in contact with the auxiliary electrode SEe may have a negative polarity opposite to the polarity of the auxiliary electrode SEe. A second portion of the insulating film 40, surrounded by the first portion, may have a positive polarity opposite to the polarity of the first portion.

The second portion of the insulating film 40 may contact the first semiconductor layer 10. Extra holes may be present in the first semiconductor layer 10, which is a p-type semiconductor layer doped with an p-type dopant. Since the second portion of the insulating film 40 has a positive polarity, a repulsive force may exist between the second portion of the insulating film 40 and the extra holes. Accordingly, the extra holes may be distributed more in the center rather than on the surface (i.e., side surface) of the first semiconductor layer 10. The extra holes may be substantially absent from the surface (i.e., side surface) of the first semiconductor layer 10, or may be relatively few. As shown in FIG. 64, the surface (i.e., side surface) of the first semiconductor layer 10 in contact with the second portion of the insulating film 40 may have a negative polarity due to the deficiency of holes.

As the extra holes are distributed more in the center rather than on the surface (i.e., side surface) of the first semiconductor layer 10, the path of movement of the holes in the first semiconductor layer 10 may also be formed in the center of the first semiconductor layer 10. Accordingly, the holes in the first semiconductor layer 10 may be concentrated toward the center instead of moving to the surface (i.e., side surface) of the first semiconductor layer 10. The holes in the first semiconductor layer 10 may be more effectively provided to the active layer 30. This may improve the light emission efficiency of the light-emitting element LD.

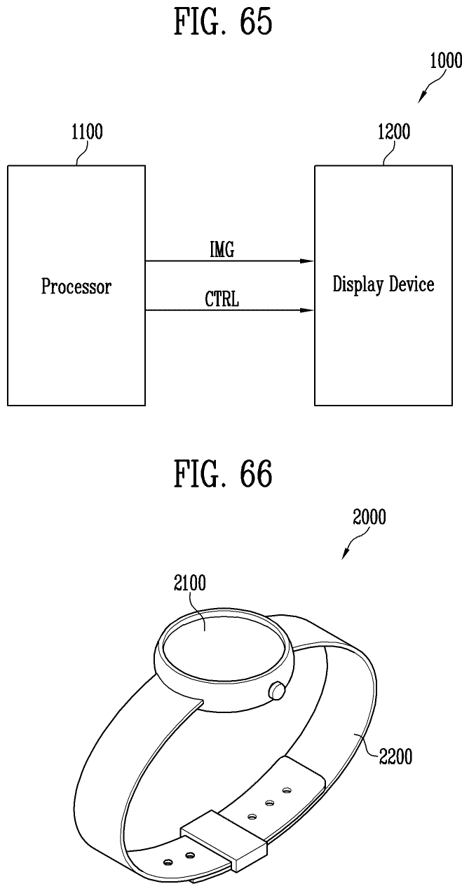

FIG. 65 is a schematic block diagram illustrating a display system according to an embodiment.

Referring to FIG. 65, the display system 1000 may include a processor 1100 and a display device 1200.

The processor 1100 may perform a variety of tasks and calculations. In embodiments, the processor 1100 may include an application processor, a graphics processor, a microprocessor, a central processing unit (CPU), or the like. The processor 1100 may be connected to other components of the display system 1000 via a bus system to control them.

The processor 1100 may transmit image data IMG and control signals CTRL to the display device 1200. The display device 1200 may display the image based on the image data IMG and the control signals CTRL. The display device 1200 may be configured similarly to the display device DD described with reference to FIG. 1. The image data IMG and control signals CTRL may be provided as the input image data IMG and control signals CTRL of FIG. 1, respectively.

The display system 1000 may include a computing system that provides image display function, such as a smart watch, a mobile phone, a smart phone, a portable computer, a tablet personal computer (PC), a watch phone, an automotive display, smart glasses, a portable multimedia player (PMP), a navigation system, an ultra-mobile personal computer (UMPC), or the like. The display system 1000 may also include at least one of a head-mounted display (HMD), a virtual reality (VR) device, a mixed reality (MR) device, and an augmented reality (AR) device.

FIGS. 66 to 69 are schematic perspective views illustrating examples of applications of the display system of FIG. 65.

Referring to FIG. 66, the display system 1000 of FIG. 65 may be applied to a smart watch 2000, which includes a display part 2100 and a strap part 2200.

The smart watch 2000 may be a wearable electronic device. For example, the smart watch 2000 may have a structure in which a strap part 2200 is mounted to a user's wrist. Here, the display system 1000 and/or the display device 1200 may be applied to the display part 2100 to provide image data, including time information, to the user.

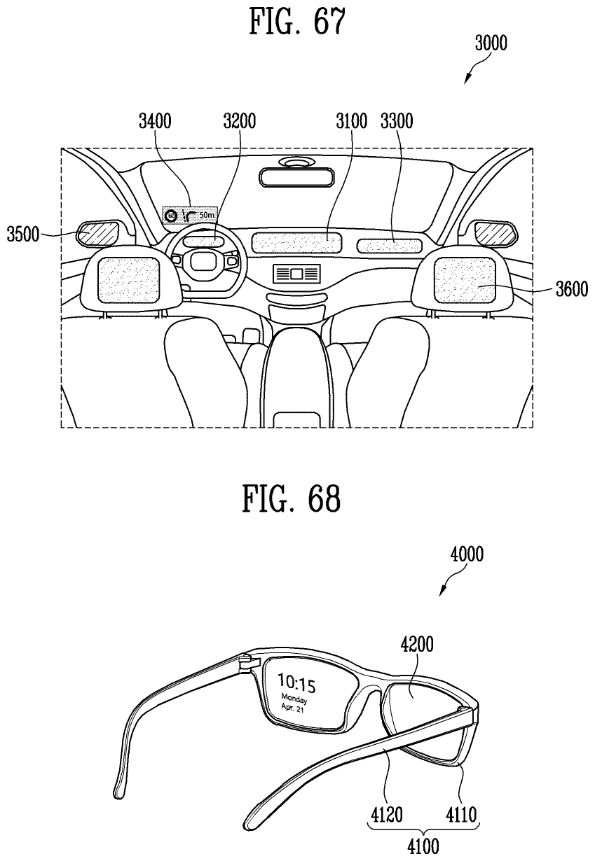

Referring to FIG. 67, the display system 1000 of FIG. 65 may be adapted to an automotive display system 3000. The automotive display system 3000 may include a computing system provided inside and/or outside the vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear seat display 3600 provided in a vehicle.

Referring to FIG. 68, the display system 1000 of FIG. 65 may be applied to smart glasses 4000. The smart glasses 4000 may be a wearable electronic device worn on a user's head. For example, the smart glasses 4000 may be a wearable device for augmented reality.

The smart glasses 4000 may include a frame 4100 and a lens part 4200. A frame 4100 may include a housing 4110 that supports the lens part 4200 and a leg part 4120 for wear by a user. The leg part 4120 may be connected to the housing 4110 via a hinge and may be foldable or unfoldable relative to the housing 4110.

A battery, a touch pad, a microphone, a camera, and the like may be embedded in the frame 4100. A projector for outputting light, a processor for controlling optical signals, and the like may be embedded in the frame 4100.

The lens part 4200 may include an optical member that transmits light or reflects light. For example, the lens part 4200 may include glass, a transparent synthetic resin, or the like.

To enable the user's eyes to recognize visual information, the lens part 4200 may reflect the image generated by the light signal transmitted from the projector in the frame 4100 on a rear surface of the lens part 4200 (for example, a surface facing the user's eyes). For example, a user may recognize visual information such as time, date, etc. displayed on the lens part 4200. The projector and/or lens part 4200 may function as a display device. The display device 1200 may be applied to the projector and/or lens part 4200.

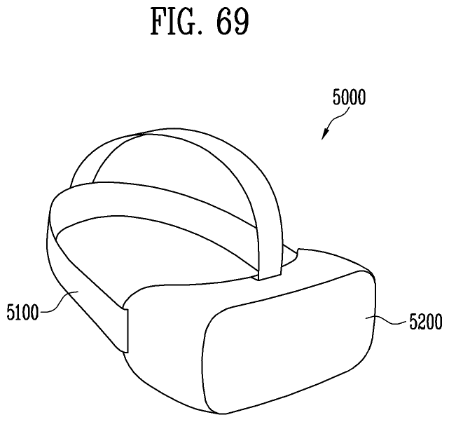

Referring to FIG. 69, the display system 1000 of FIG. 65 may be applied to a head-mounted display device 5000.

The head-mounted display device 5000 may be a wearable electronic device worn on a user's head. For example, the head-mounted display device 5000 may be a wearable device for virtual reality or mixed reality.

The head-mounted display device 5000 may include a head-mounted band 5100 and a display device receiving case 5200. The head-mounted band 5100 may be connected to the display device receiving case 5200. The head-mounted band 5100 may include a horizontal band and/or a vertical band for securing the head-mounted display device 5000 to a user's head. The horizontal band may wrap around a side portion of the user's head, while the vertical band may wrap around an upper portion of the user's head. However, the embodiments are not limited thereto. For example, the head-mounted band 5100 may be implemented in the form of an eyeglass frame, a helmet, or the like.

The display device receiving case 5200 may house the display system 1000 and/or the display device 1200.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
an anode electrode;
a cathode electrode disposed on the anode electrode;
a light-emitting element disposed between the anode electrode and the cathode electrode; and
an auxiliary electrode surrounding a side surface of the light-emitting element, wherein the light-emitting element includes:
a bonding electrode connected to the anode electrode;
a light-emitting member including a first semiconductor layer connected to the bonding electrode, a second semiconductor layer connected to the cathode electrode and disposed on the first semiconductor layer, and an active layer disposed between the first semiconductor layer and the second semiconductor layer; and
an insulating film covering at least a side surface of the light-emitting member, and
a portion of the auxiliary electrode surrounding the side surface of the light-emitting element is disposed above an upper surface of the active layer.

2. The display device of claim 1, wherein the auxiliary electrode is in contact with the cathode electrode.

3. The display device of claim 2, wherein the auxiliary electrode extends from the side surface of the light-emitting element and covers the entire upper surface of the light-emitting element.

4. The display device of claim 3, wherein the auxiliary electrode may be disposed between the cathode electrode and the upper surface of the second semiconductor layer.

5. The display device of claim 1, wherein the auxiliary electrode is in direct contact with the insulating film.

6. The display device of claim 1, further comprising:
a first passivation layer disposed on the anode electrode, wherein
the light-emitting element is partially buried in the first passivation layer.

7. The display device of claim 6, wherein a height of the upper surface of the first passivation layer is equal to or higher than a height of the upper surface of the active layer.

8. The display device of claim 7, wherein the auxiliary electrode is disposed on the first passivation layer.

9. The display device of claim 1, wherein the auxiliary electrode is spaced apart from the cathode electrode.

10. The display device of claim 9, further comprising:
an auxiliary voltage line connected to the auxiliary electrode.

11. A display device comprising:
an anode electrode;
a cathode electrode disposed on the anode electrode;
a light-emitting element disposed between the anode electrode and the cathode electrode; and
an auxiliary electrode surrounding a side surface of the light-emitting element, wherein the light-emitting element includes:
a bonding electrode connected to the anode electrode;
a light-emitting member including a first semiconductor layer connected to the bonding electrode, a second semiconductor layer connected to the cathode electrode and disposed on the first semiconductor layer, and an active layer disposed between the first semiconductor layer and the second semiconductor layer; and
an insulating film covering at least a side surface of the light-emitting member, and
a portion of the auxiliary electrode surrounding the side surface of the light-emitting element is disposed below a lower surface of the active layer.

12. The display device of claim 11, wherein the auxiliary electrode is in direct contact with the insulating film.

13. The display device of claim 11, further comprising:
a first passivation layer disposed on the anode electrode; and
a second passivation layer disposed on the first passivation layer, wherein
the light-emitting element is partially buried in the first and second passivation layers.

14. The display device of claim 13, wherein a height of an upper surface of the second passivation layer is equal to or lower than a height of the lower surface of the active layer.

15. The display device of claim 14, wherein the auxiliary electrode is disposed on the first passivation layer.

16. The display device of claim 11, further comprising:
an auxiliary voltage line connected to the auxiliary electrode.

17. An electronic device comprising:
a processor that provides image data; and
a display device that displays an image based on the image data, wherein
the display device includes:
an anode electrode;
a cathode electrode disposed on the anode electrode; and
a light-emitting element disposed between the anode electrode and the cathode electrode, wherein
the light-emitting element includes:
a bonding electrode connected to the anode electrode;
an auxiliary electrode disposed on the bonding electrode;
a light-emitting member including a first semiconductor layer connected to the auxiliary electrode, a second semiconductor layer connected to the cathode electrode and disposed on the first semiconductor layer, and an active layer disposed between the first semiconductor layer and the second semiconductor layer; and
an insulating film covering at least a side surface of the light-emitting member, and
the auxiliary electrode surrounds a side surface of the first semiconductor layer below the active layer.

18. The electronic device of claim 17, wherein the insulating film is disposed between the auxiliary electrode and the side surface of the first semiconductor layer.

19. The electronic device of claim 17, wherein the auxiliary electrode is in direct contact with at least a portion of a lower surface of the first semiconductor layer.

20. The electronic device of claim 17, wherein the auxiliary electrode includes a light-reflective conductive material.
